(19) United States
(12) Patent Application Publication
(10) Pub. No.: US 2026/0296881 A1
(43) Pub. Date: Oct. 1, 2026

(54) MANUFACTURING A MICROPHONE BY BONDING LAYERS

(71) Applicant: InvenSense, Inc., San Jose, CA (US)

(72) Inventor: Jotaro Akiyama, Minami (JP)

(21) Appl. No.: 19/089,693

(22) Filed: Mar. 25, 2025

(51) Int. Cl. B81C 1/00; H04R 7/04; H04R 19/04; H04R 31/00

(52) U.S. Cl. CPC B81C 1/00158; H04R 7/04; H04R 19/04; H04R 31/003; H04R 31/006; B81C 2201/013; B81C 2203/036; H04R 2201/003

(57) ABSTRACT

A method includes forming a cavity on a second side of a first layer. The second side of the first layer faces away from a first side of the first layer. The method further includes forming an electrode on the first layer within the cavity. In one nonlimiting example, the method also includes bonding the second side of the first layer to a second side of a second layer to form a sealed cavity between the first layer and the second layer. The second side of the second layer faces away from a first side of the second layer. According to one nonlimiting example, a portion of the second layer that forms the sealed cavity is a deformable membrane. The deformable membrane vibrates in response to external pressure.

### BACKGROUND

MEMS (“micro-electro-mechanical systems”) are a class of devices that are fabricated using semiconductor-like processes and exhibit mechanical characteristics. For example, MEMS devices may include the ability to move or deform. In many cases, but not always, MEMS interact with electrical signals. A MEMS device may refer to a semiconductor device that is implemented as a micro-electro-mechanical system. A MEMS device includes mechanical elements and may optionally include electronics (e.g., electronics for sensing). MEMS devices include but are not limited to, for example, gyroscopes, accelerometers, magnetometers, pressure sensors, microphone, etc.

A microphone may be manufactured using MEMS by performing layer deposition, mask patterning, and/or etching. In general, signal to noise ratio (SNR) of the microphone is limited by air damping between membrane and backplate. Introducing sealed cavity enclosed by membrane and backplate and reducing the air pressure within the cavity to levels close to vacuum improves SNR. As such, conventionally the internal cavity is released and sealed. Unfortunately, controlling the gap between the electrodes by forming the internal cavity by releasing and sealing is complicated and difficult to control. Additionally, it is often difficult to achieve the vacuum levels for the cavity that are desired. Moreover, layer deposition of the conventional methods is time consuming because the deposition steps are performed in chronological ordering without ability to be processed in parallel to one another. Achieving the required rigidity for the backplate (to suppress unwanted resonance) is also difficult to achieve using the conventional deposition methodology.

### SUMMARY

Accordingly, a need has arisen to manufacture a microphone using MEMS such that different layers can be processed concurrently in order to reduce the manufacturing time. Additionally, a need has arisen to form a backplate that is sufficiently rigid (e.g., by being thick) to reduce the unwanted resonances. Additionally, a need has arisen to eliminate an internal cavity release and reseal while enabling the gap between the electrodes to be controlled more precisely and to improve the cavity seal. Accordingly, two layers, e.g., backplate layer and membrane layer, may be processed concurrently to create the features including the gap (e.g., standoff) in the controlled fashion. Subsequently the two layers are bonded together and subsequently processed to form electrical contacts and/or create an acoustic port. In some embodiments, electrical node-to-node isolation may be provided by creating isolation trench in the backplate layer and filling the trenches with isolation material, e.g., oxide.

A method includes forming a cavity on a second side of a first layer. The second side of the first layer faces away from a first side of the first layer. The method further includes bonding the second side of the first layer to a second side of a second layer. The second side of the second layer faces away from a first side of the second layer. The bonding seals the cavity between the second side of the first layer and the second side of the second layer. The method also includes etching a portion of the first side of the second layer. The second layer forms a deformable membrane.

In one nonlimiting example, the method further includes forming a plurality of electrically isolation regions within the first layer, e.g., the plurality of electrically isolated regions within the first layer is formed by forming a plurality of trenches within the second side of the first layer and by forming thermal oxidation within the plurality of trenches and on the second side of the first layer. The method may further include thinning the first layer from the first side of the first layer to expose a surface of the plurality of electrically isolation regions. Moreover, the method may further include depositing an insulator, e.g., silicon dioxide, silicon nitride, etc., on the exposed surface of the plurality of electrically isolated region and further on a portion of the first side of the first layer that is exposed. In one nonlimiting example, the method further includes etching the cavity to form a plurality of cavities and protruding portions, wherein the protruding portions form backplate electrodes. In one nonlimiting example, the method includes forming a first standoff outside the cavity on the second side of the first layer. In some embodiments, the method further includes forming a center standoff on the second side of the first layer. In one nonlimiting example, a height of the center standoff is controlled through a thermal oxidation. According to one nonlimiting example, the first standoff and the center standoff are formed from an insulator layer, e.g., silicon dioxide or silicon nitride. According to one nonlimiting example, the bonding comprises forming fusion bonding the first standoff and the center standoff to the second layer.

According to one nonlimiting example, the method further includes forming at least one or more electrical contacts on the first side of the first layer, wherein the one or more electrical contacts is formed on another portion of the first side of the first layer that is exposed. It is appreciated that a passivation layer may be formed on the first side of the first layer and between the at least one or more electrical contacts.

A method includes forming a cavity on a second side of a first layer. The second side of the first layer faces away from a first side of the first layer. The method further includes forming an electrode on the first layer within the cavity. In one nonlimiting example, the method also includes bonding the second side of the first layer to a second side of a second layer to form a sealed cavity between the first layer and the second layer. The second side of the second layer faces away from a first side of the second layer. According to one nonlimiting example, a portion of the second layer that forms the sealed cavity is a deformable membrane. The deformable membrane vibrates in response to external pressure.

According to one nonlimiting example, the method includes etching a portion of the second layer from the first side to form an acoustic port, e.g., etching a silicon dioxide layer on the second layer to expose the deformable membrane. The method may further include forming a plurality of electrically isolation regions within the first layer. In one nonlimiting example, the plurality of electrically isolated regions within the first layer is formed by forming a plurality of trenches within the second side of the first layer and by forming thermal oxidation within the plurality of trenches and on the second side of the first layer. The first layer from the first side of the first layer may be thinned to expose a surface of the plurality of electrically isolation regions. The method may also include depositing an insulator layer on the exposed surface of the plurality of electrically isolated region and further on a portion of the first side of the first layer that is exposed. In one nonlimiting example, the method includes forming at least one or more electrical contacts on the first side of the first layer, wherein the one or more electrical contacts is formed on another portion of the first side of the first layer that is exposed. According to some embodiments, the method also includes forming a passivation layer on the first side of the first layer and between the at least one or more electrical contacts. In some nonlimiting examples, the method also includes forming a first standoff outside the cavity of the second side of the first layer and forming a second standoff (e.g., silicon dioxide) on the second side of the first layer, wherein the first standoff and the second standoff are bonded (e.g., fusion bond between silicon dioxide) to the polysilicon layer of the second layer. The method may also include etching the cavity in the first layer to form a plurality of cavities and protruding portions, wherein the protruding portions form backplate electrodes.

These and other features and advantages will be apparent from a reading of the following detailed description.

### BRIEF DESCRIPTION OF DRAWINGS

FIGS. 1-12 show processing of a backplate according to one aspect of the present embodiments.

FIGS. 13-14 show bonding the backplate to a membrane layer according to one aspect of the present embodiments.

FIGS. 15-20 show processing of the bonded layers and forming electrical contacts according to one aspect of the present embodiments.

FIGS. 21-22 show processing of the bonded layers to form an acoustic port according to one aspect of the present embodiments.

FIG. 23 shows forming electrical connection between the electrical contacts according to one aspect of the present embodiments.

FIG. 24 shows a flow diagram for forming the microphone device according to one aspect of the present embodiments.

FIGS. 25-29 show another nonlimiting example of forming a backplate of the microphone device according to one aspect of the present embodiments.

FIG. 30 shows bonding the backplate of the microphone device to a membrane layer according to one aspect of the present embodiments.

FIGS. 31-34 show forming electrical connections on the backplate of the microphone device according to one aspect of the present embodiments.

FIGS. 35-36 show forming an acoustic port of the microphone device according to one aspect of the present embodiments.

FIG. 37 shows a flow diagram for forming the microphone device according to another aspect of the present embodiments.

### DESCRIPTION

Before various embodiments are described in greater detail, it should be understood that the embodiments are not limiting, as elements in such embodiments may vary. It should likewise be understood that a particular embodiment described and/or illustrated herein has elements which may be readily separated from the particular embodiment and optionally combined with any of several other embodiments or substituted for elements in any of several other embodiments described herein.

It should also be understood that the terminology used herein is for the purpose of describing certain concepts, and the terminology is not intended to be limiting. Unless defined otherwise, all technical and scientific terms used herein have the same meaning as commonly understood in the art to which the embodiments pertain.

Unless indicated otherwise, ordinal numbers (e.g., first, second, third, etc.) are used to distinguish or identify different elements or steps in a group of elements or steps, and do not supply a serial or numerical limitation on the elements or steps of the embodiments thereof. For example, “first,” “second,” and “third” elements or steps need not necessarily appear in that order, and the embodiments thereof need not necessarily be limited to three elements or steps. It should also be understood that, unless indicated otherwise, any labels such as “left,” “right,” “front,” “back,” “top,” “middle,” “bottom,” “beside,” “forward,” “reverse,” “overlying,” “underlying,” “up,” “down,” or other similar terms such as “upper,” “lower,” “above,” “below,” “under,” “between,” “over,” “vertical,” “horizontal,” “proximal,” “distal,” and the like are used for convenience and are not intended to imply, for example, any particular fixed location, orientation, or direction. Instead, such labels are used to reflect, for example, relative location, orientation, or directions. It should also be understood that the singular forms of “a,” “an,” and “the” include plural references unless the context clearly dictates otherwise.

Terms such as “over,” “overlying,” “above,” “under,” etc. are understood to refer to elements that may be in direct contact or may have other elements in-between. For example, two layers may be in overlying contact, wherein one layer is over another layer and the two layers physically contact. In another example, two layers may be separated by one or more layers, wherein a first layer is over a second layer and one or more intermediate layers are between the first and second layers, such that the first and second layers do not physically contact.

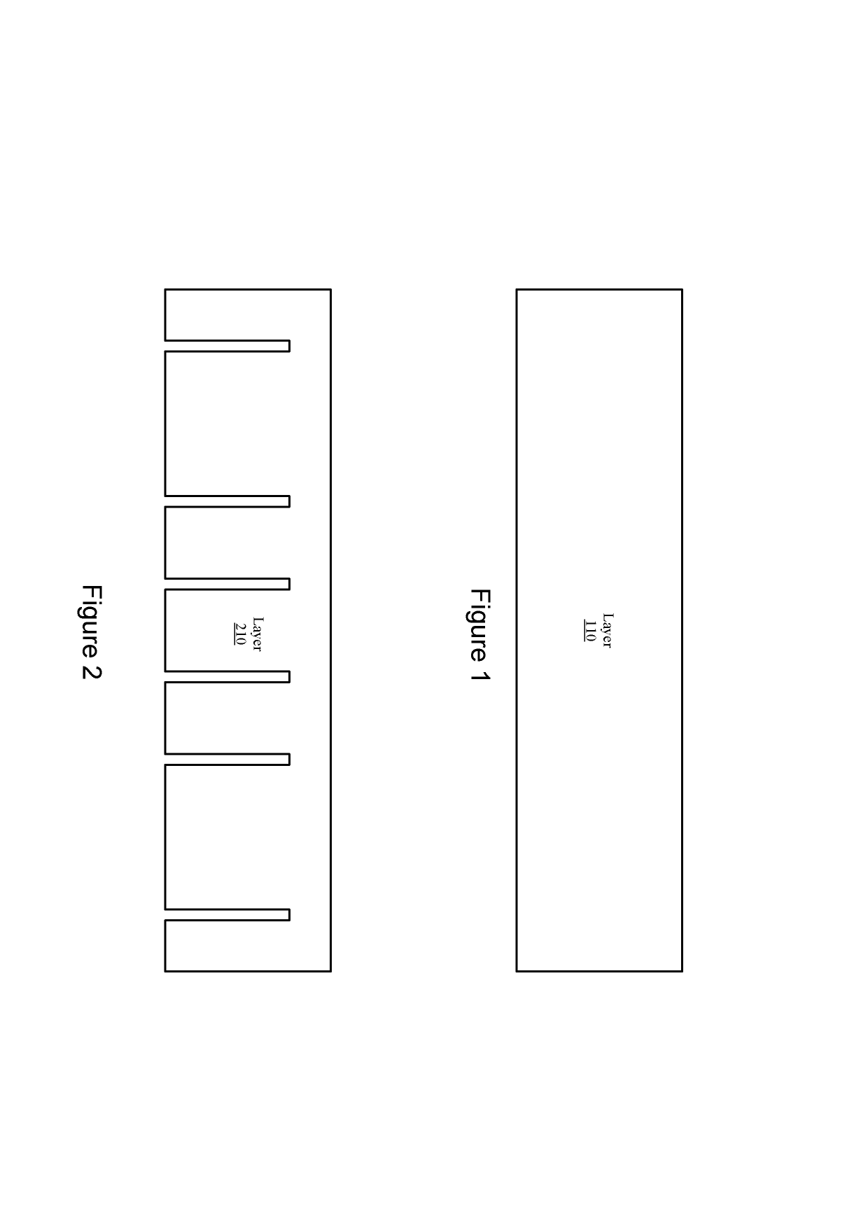

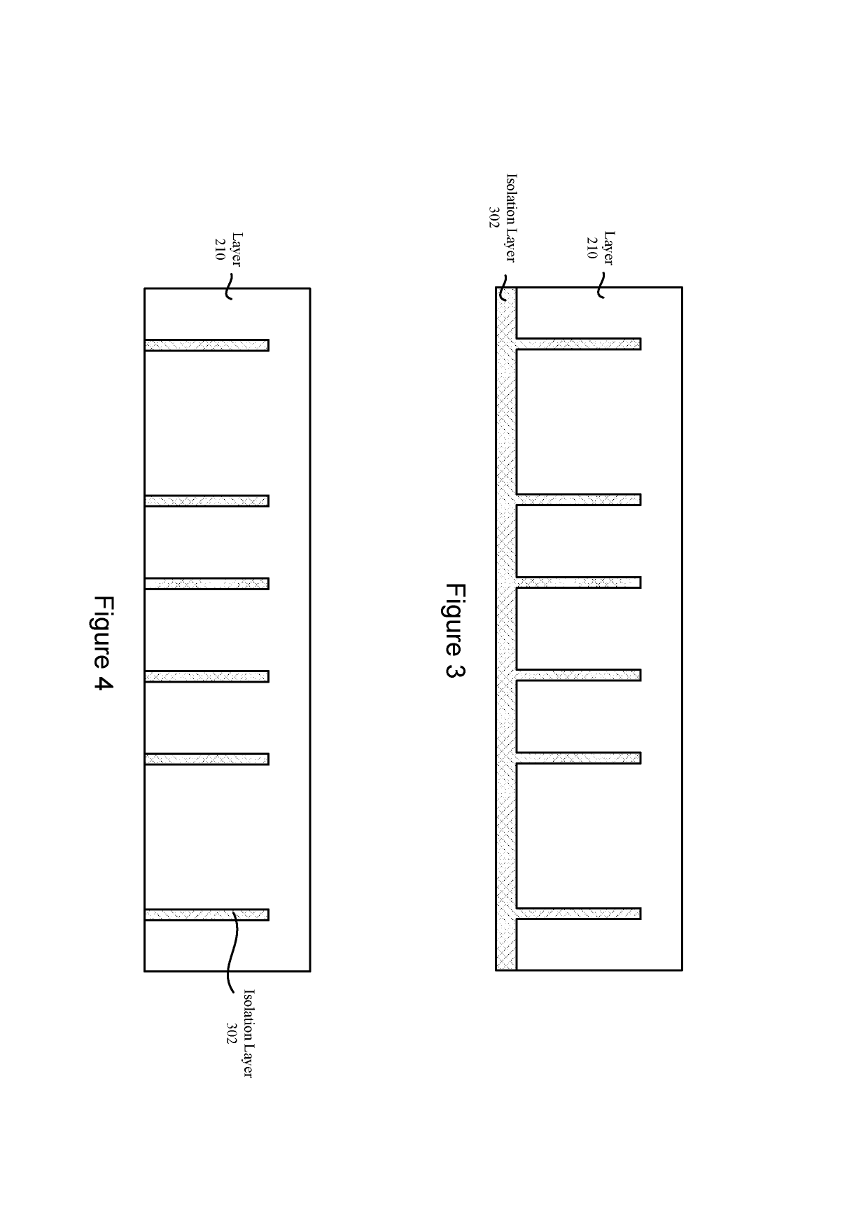

FIGS. 1-12 show processing of a backplate according to one aspect of the present embodiments. More specifically, referring to FIG. 1, a layer 110 is shown. The layer 110 may be a wafer, e.g., bulk silicon, and may be referred to as the backplate layer. The layer 110 may be highly doped low resistance. The layer 110 has a first side (e.g., facing up) and a second side (facing down) that face away from one another. Referring now to FIG. 2, a plurality of trenches is formed in the layer 110 to form a layer 210. The plurality of trenches may be formed using deep reactive ion etching (DRIE) trench patterning to form a plurality of isolation regions (electrically isolation regions). For example, a mask (e.g., SiO2 hardmask) may be deposited on the second side of the layer 110 and patterned and subsequently DRIE process may be used to form the plurality of trenches in the layer 110 and to form the layer 210. The mask may subsequently be removed. In one nonlimiting example, the isolation pattern in the layer 210 is approximately 2 µm wide and approximately 40 µm deep.

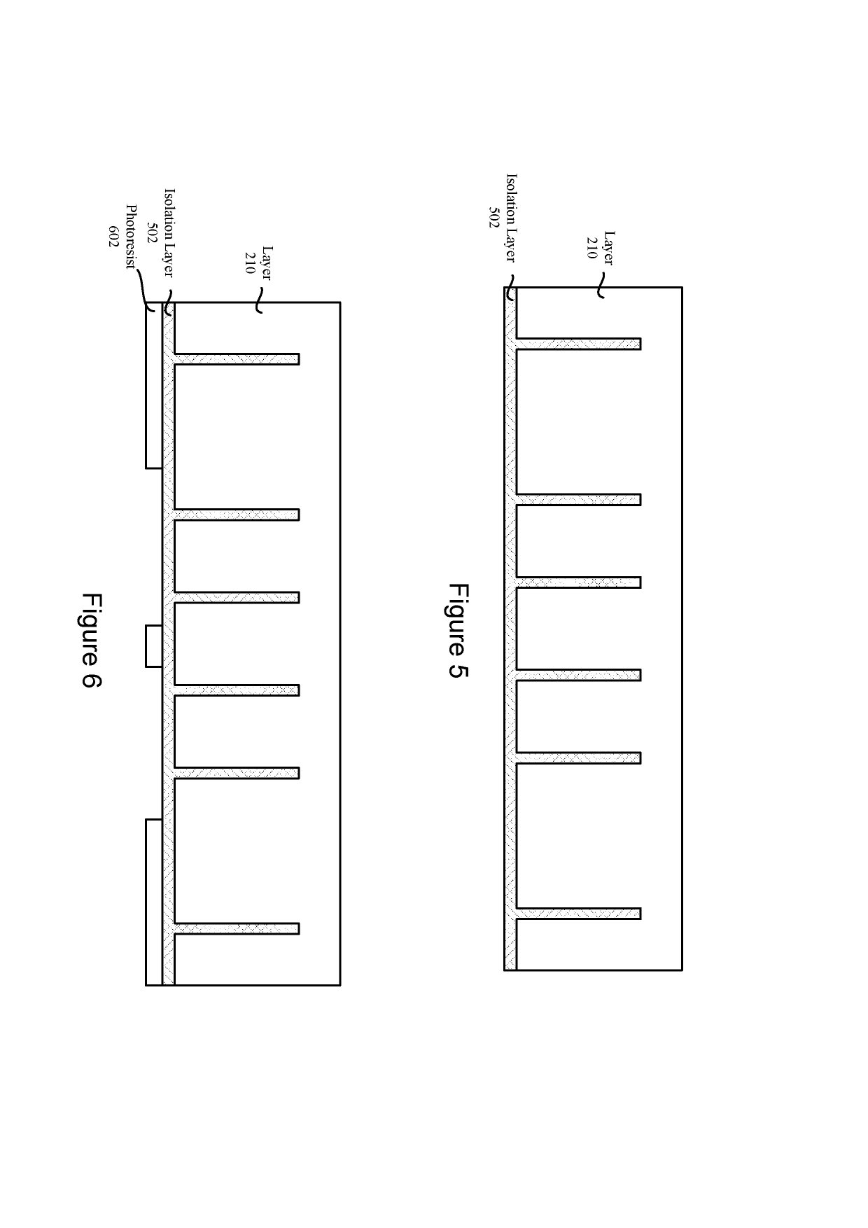

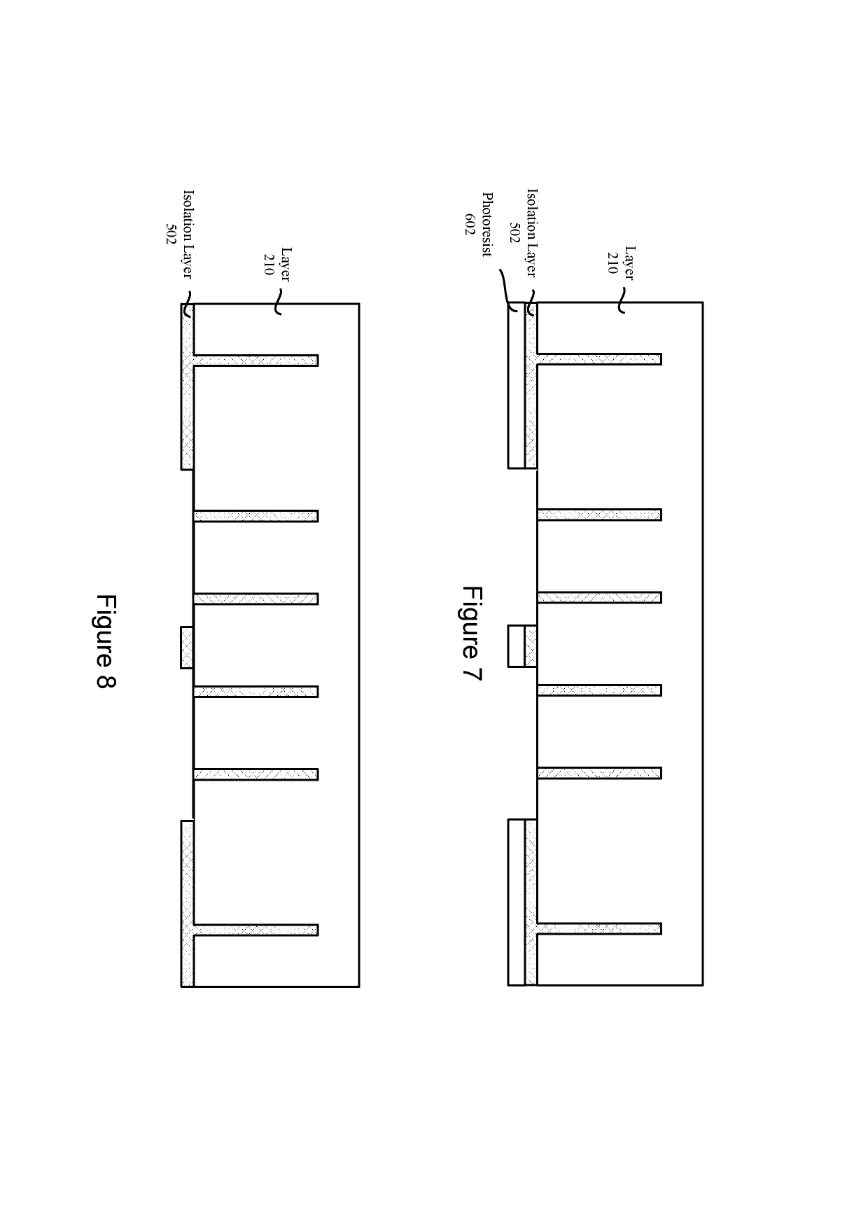

Referring now to FIG. 3, the plurality of trenches of the layer 210 is filled with isolation material 302, e.g., thermal oxidation. Thermal oxidation may be formed by 1100C wet oxidation. Referring now to FIG. 4, isolation material 302 formed on the second side of the layer 210 is removed, e.g., using SiO2 chemical mechanical polishing (CMP), to expose the bulk silicon surface of the layer 210 (on the second side) except for isolation material that fills the isolation trenches. The second side of the layer 210 is exposed in order to form a gap between two electrodes (described later in detail) by forming one or more standoff.

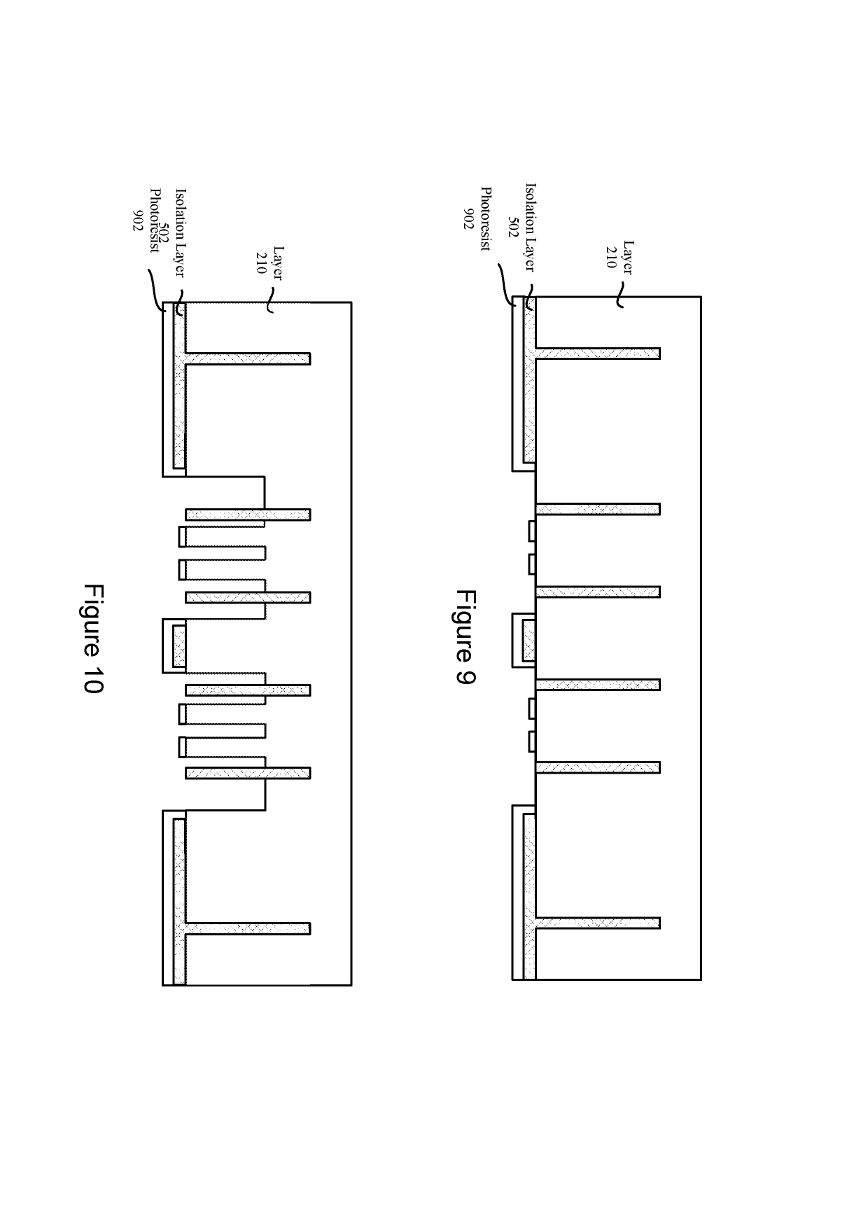

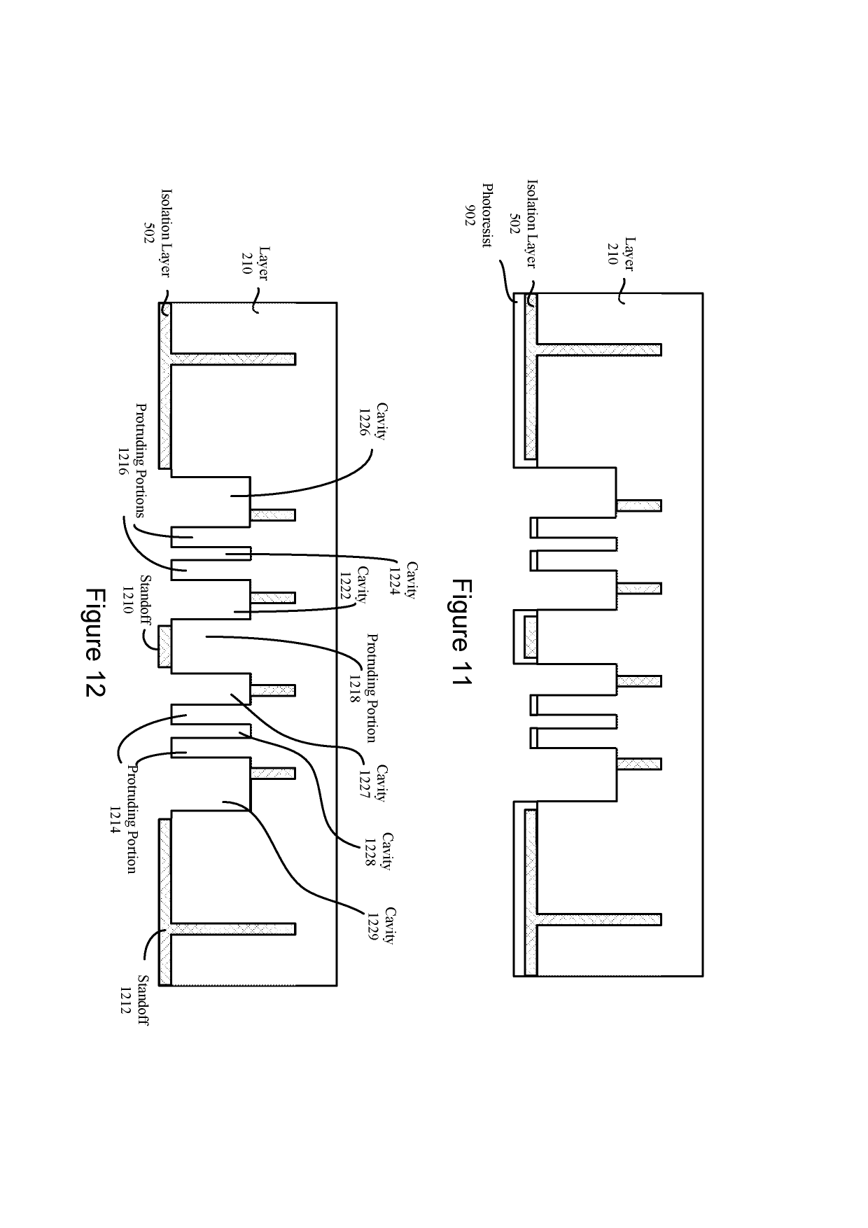

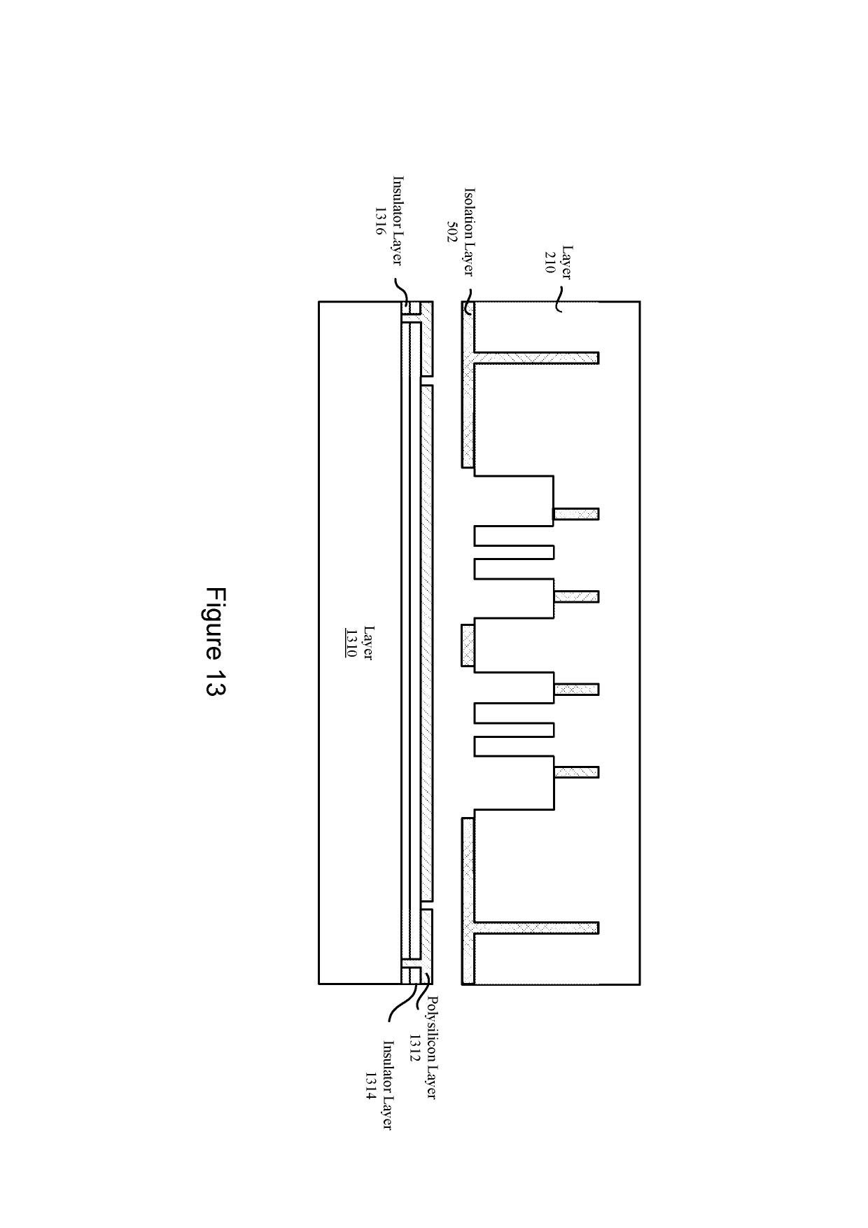

Referring now to FIG. 5, an isolation layer 502 may be formed on the second side of the layer 210 where the thickness of the isolation layer 502 controls the gap between the electrodes, as described in greater detail below. In one nonlimiting example, the isolation layer 502 may be a thermal oxide and may have a thickness of approximately 300 nm. In yet another nonlimiting example, the isolation layer 502 may be deposition of SiO2 layer and anneal process. Referring now to FIG. 6, a photoresist 602 is formed over the isolation layer 502 and is patterned such that certain portions of the isolation layer 502 (covered by the photoresist 602) is protected from the subsequent etching process. Referring now to FIG. 7, the exposed portions of the isolation layer 502 (not covered by the photoresist 602) is etched. Referring now to FIG. 8, the photoresist 602 is removed.

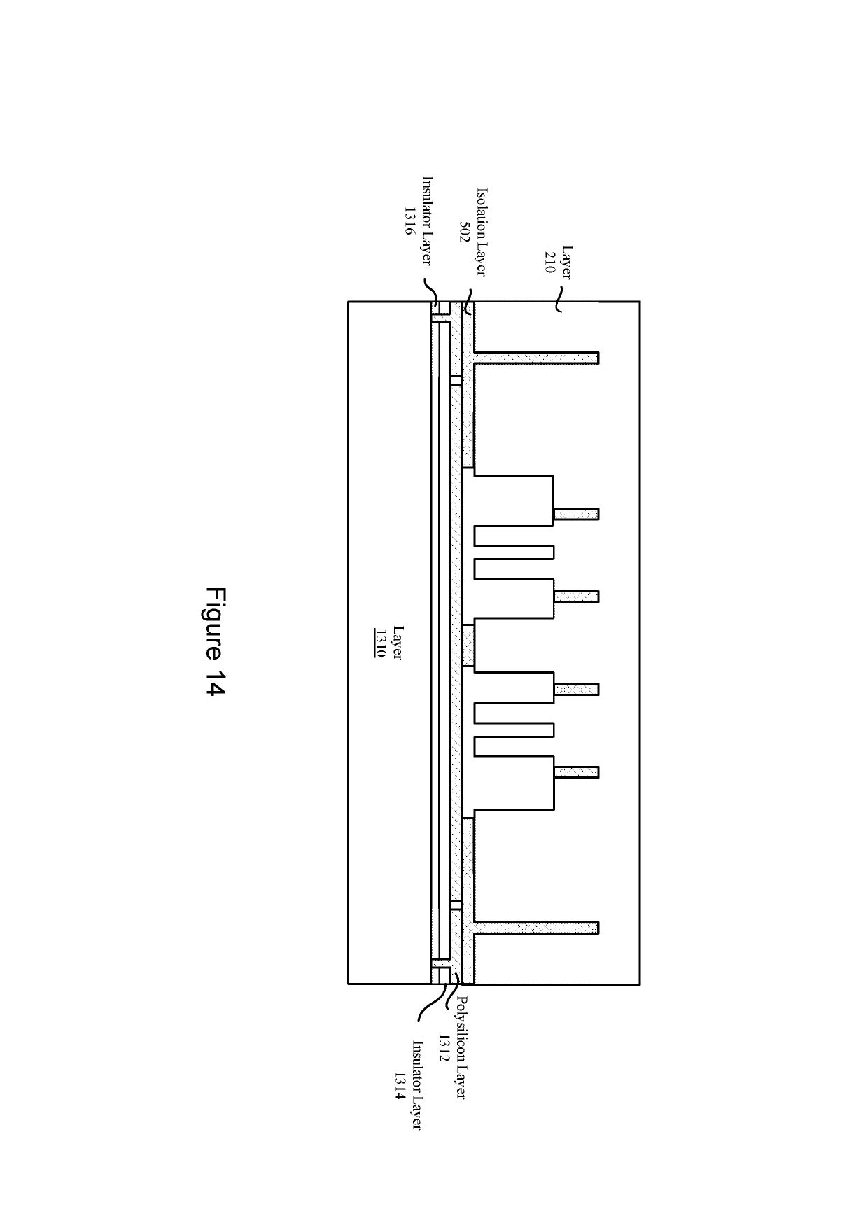

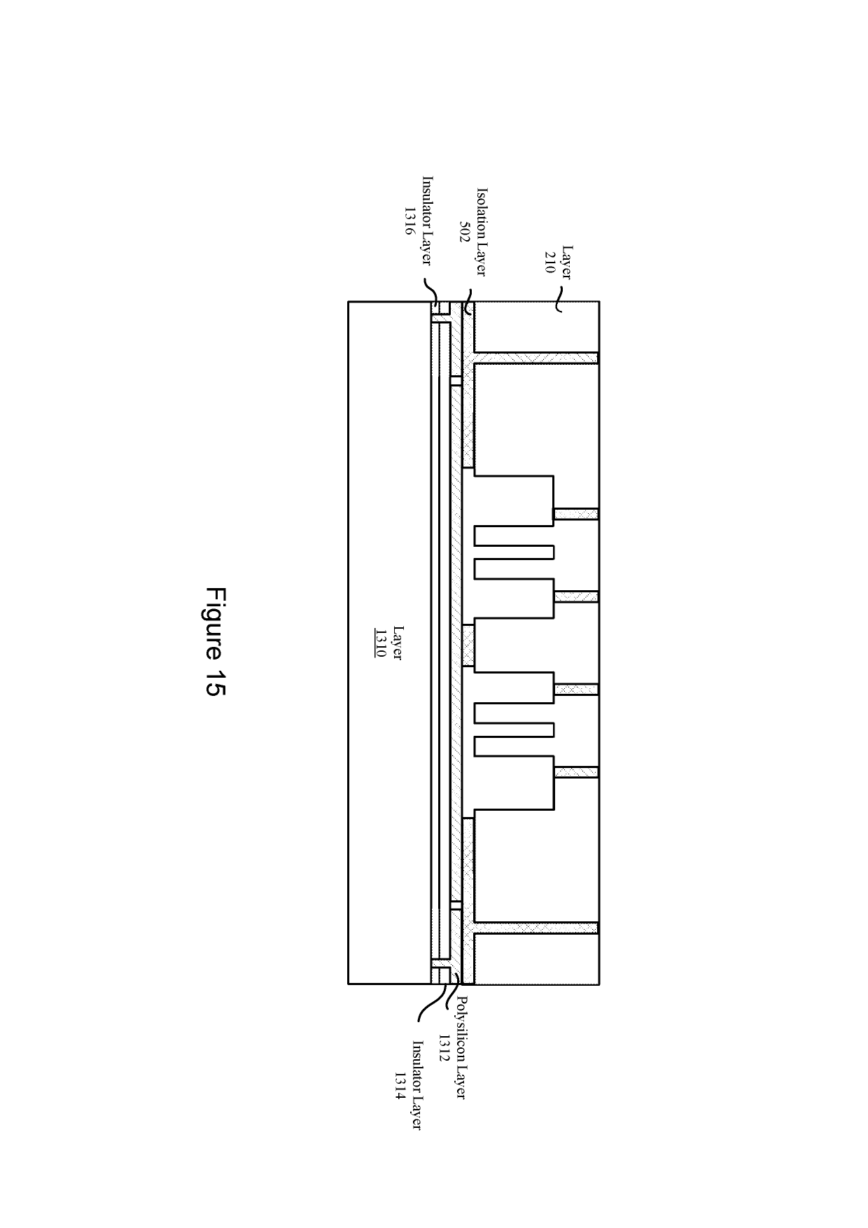

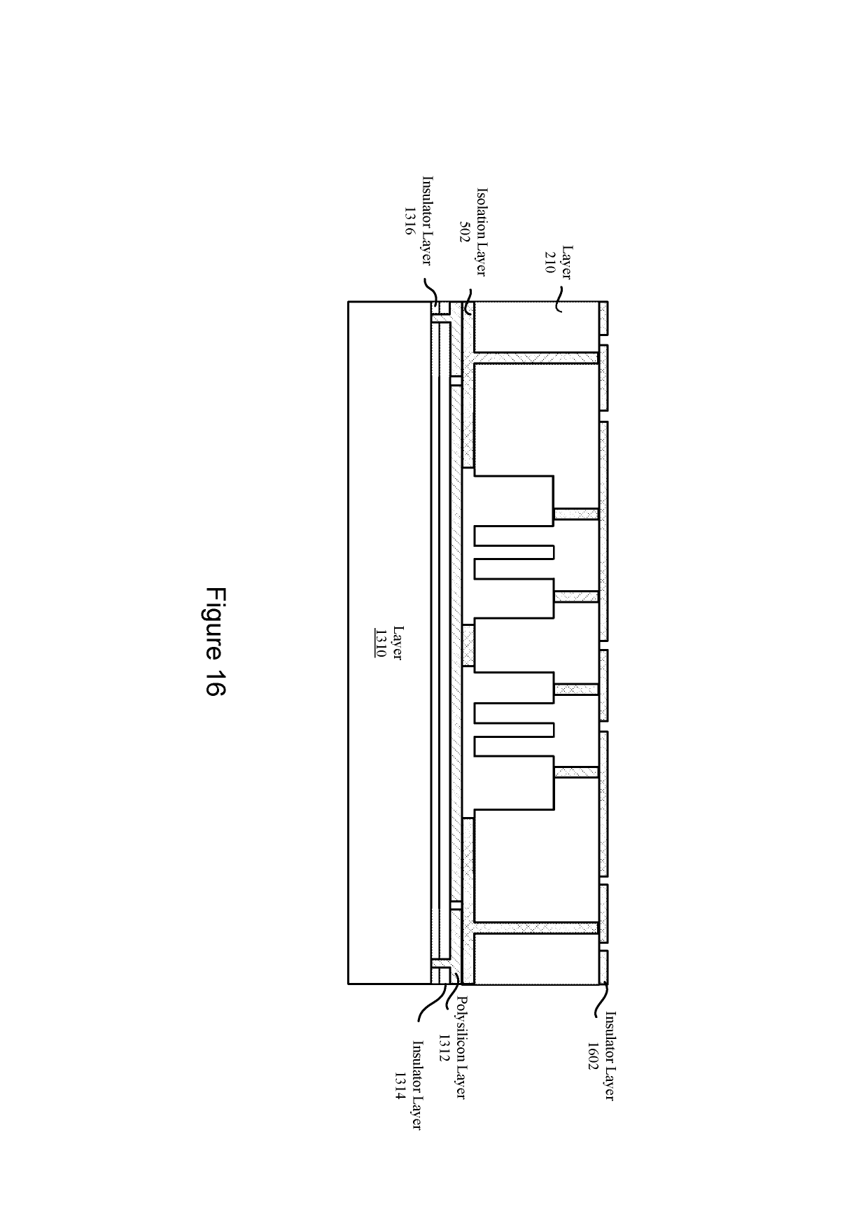

Referring now to FIG. 9, a photoresist 902 is deposited over the isolation layer 502 and further on the exposed surface of layer 210 and subsequently patterned, e.g., buffer oxide etch (BOE) to have high selectivity to silicon. Patterning the photoresist 902 protects the standoff that forms a gap between the two electrodes (described later in greater detail). Referring now to FIG. 10, the exposed portion of the layer 210 is etched (e.g., DRIE) to form one or more cavities on the second side of the layer 210 and further form outlines of sense electrode on the backplate. It is appreciated that etching, as shown in FIG. 10, results in the isolation material 302 within one or more isolation trenches to become exposed. Referring now to FIG. 11, the exposed isolation material 302, e.g., thermal oxidation, SiO2, etc., extruding out from the isolation trenches is removed, e.g., SiO2 etch, wet BOE, etc. Referring now to FIG. 12, the photoresist 902 is removed and high temperature anneal may be used to remove residue from the layer 210. As illustrated the etching as described in FIG. 10 forms protruding portions 1214, 1216, and 1218 and cavities 1222, 1224, and 1226-1229. The isolation layer 502 that remains on the second side of the layer 210 forms standoffs 1210 and 1212. The standoff 1210 is a center standoff within the cavity while standoff 1212 is a side standoff and outside of the cavity.

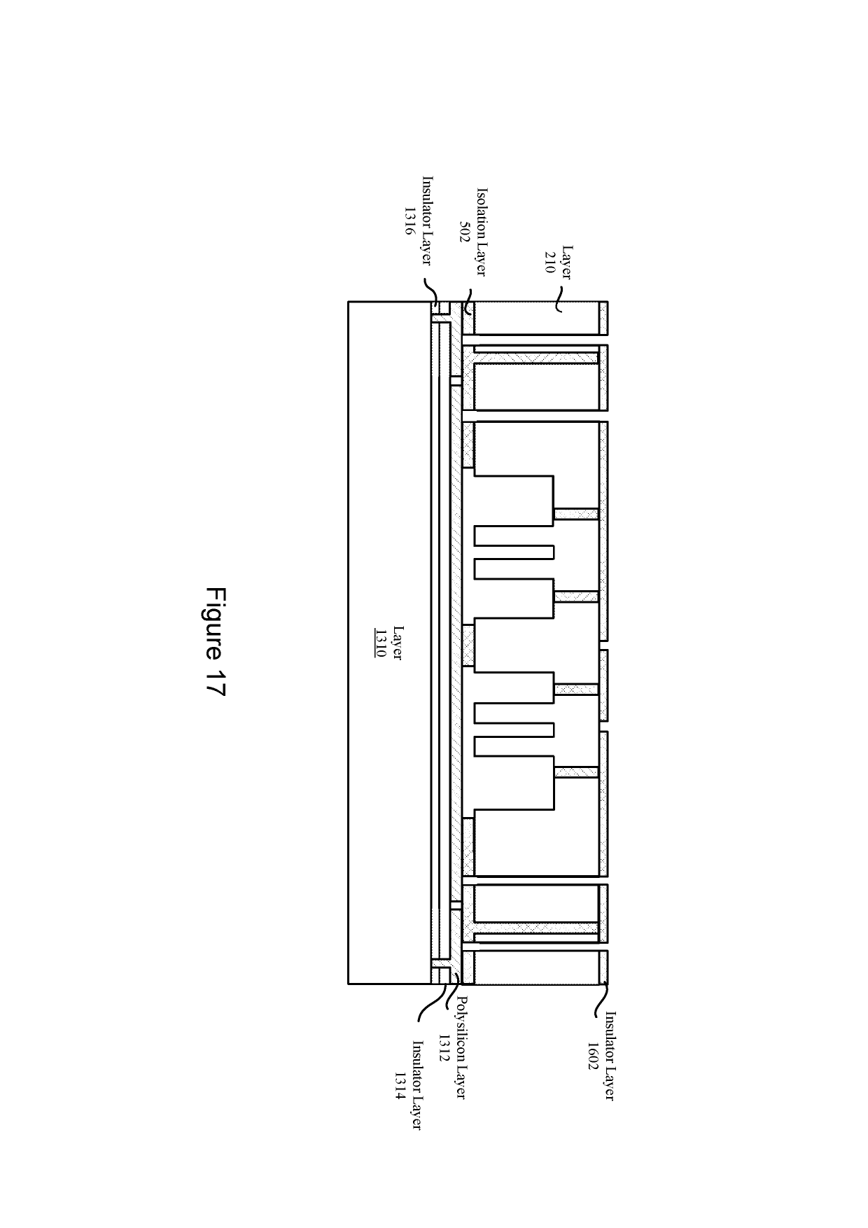

Referring now to FIG. 13, the backplate layer of FIG. 12 before bonding to the membrane layer. In one nonlimiting example, the membrane layer may include a layer 1310, e.g., bulk silicon, having a first side (e.g., facing down) and a second side (e.g., facing up) that face away from one another. Insulator layers 1316, e.g., SiO2, and 1314, e.g., Silicon Nitride (SiN), may be deposited on the second side of the layer 1310 and patterned. Subsequently a polysilicon layer 1312 is deposited and patterned to cover an exposed portion of the second side of the layer 1310 as well as covering a portion of the insulator layer 1314. Referring now to FIG. 14, the bonding, e.g., fusion bonding, of the backplate to the membrane layer is shown. In one nonlimiting example, the bonding may be performed under relatively low vacuum pressure, e.g., less than 1 Pa. It is appreciated that the bonding results in the isolation layer 502 on the second side of the layer 210 to be bonded to the polysilicon layer 1312 deposited on the second side of the layer 1310. In one nonlimiting example, molecules may be diffused out from the cavity by an anneal process or by opening a vent later and subsequently sputtering it to seal the vent. Accordingly, the cavities are sealed. The isolation layer 502 forms the standoff (on the periphery and also center) that controls the gap between the electrodes. The sensing electrodes may be formed on a bottom surface of the protruding portions 1216 and 1214 that separated from sensing electrodes, e.g., polysilicon layer 1312, formed on the second side of the layer 1310, using the gap as controlled by the thickness of the isolation layer 502 (e.g., standoffs 1210 and 1212).

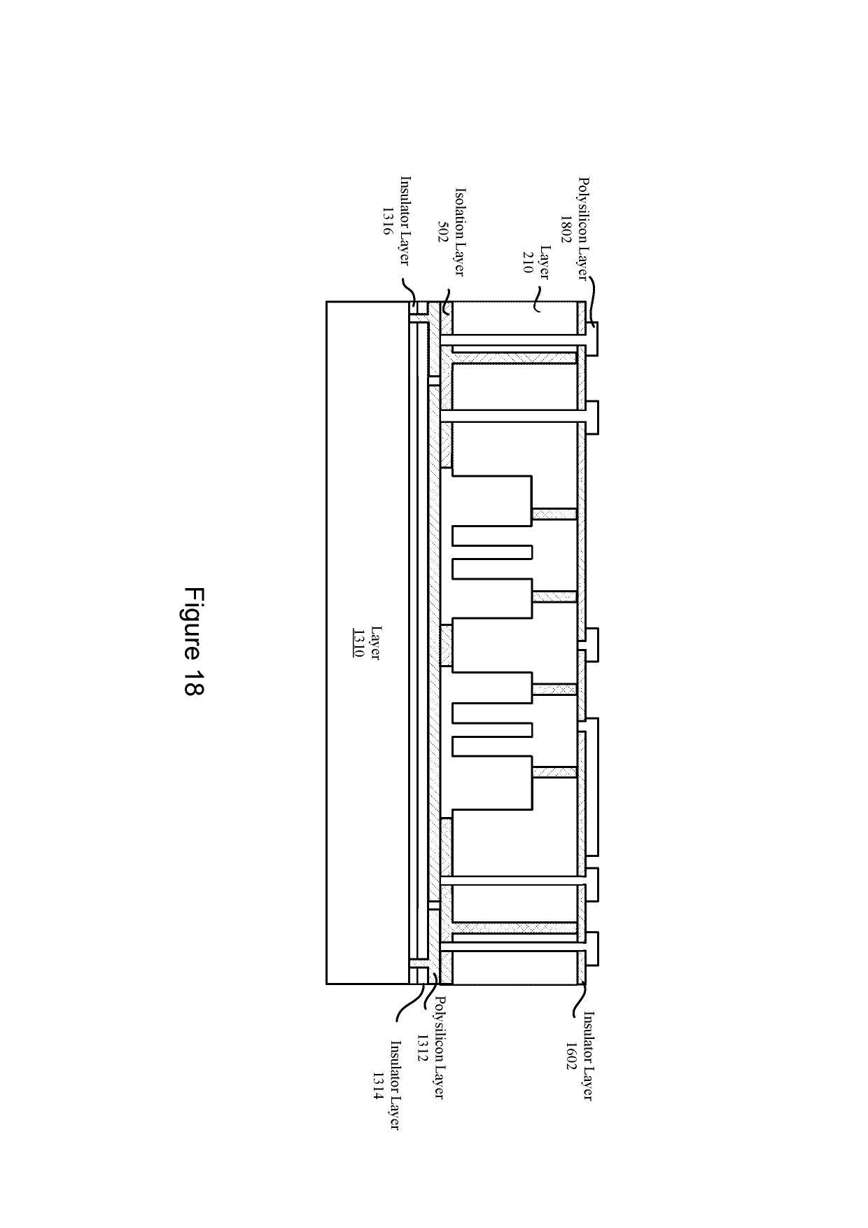

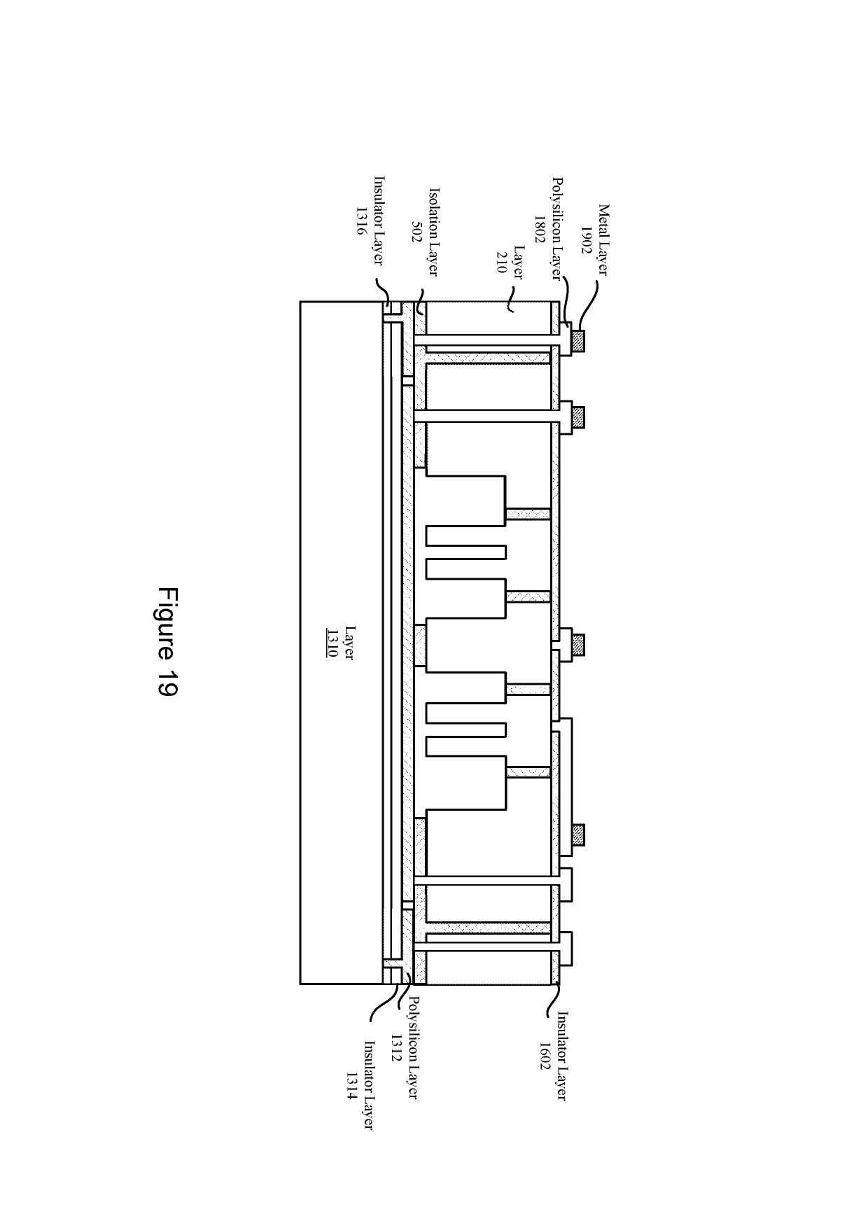

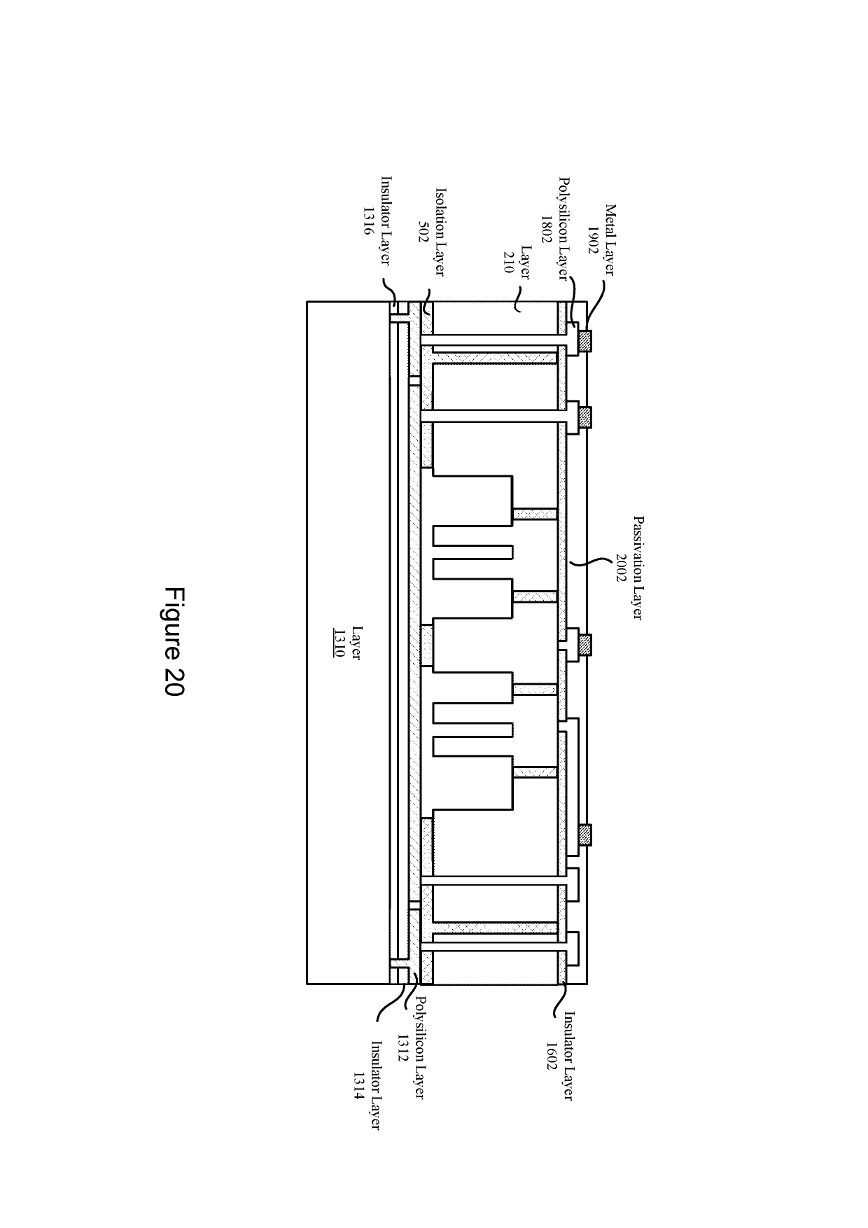

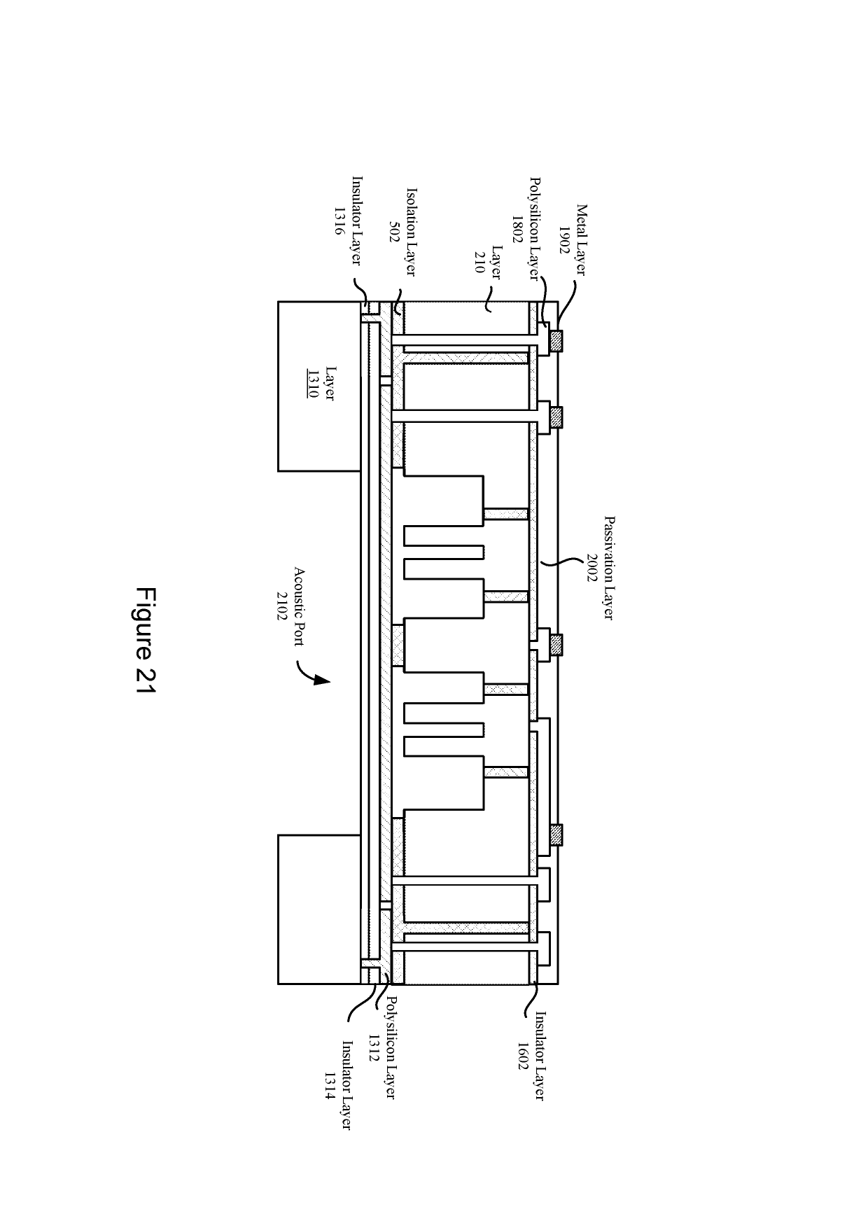

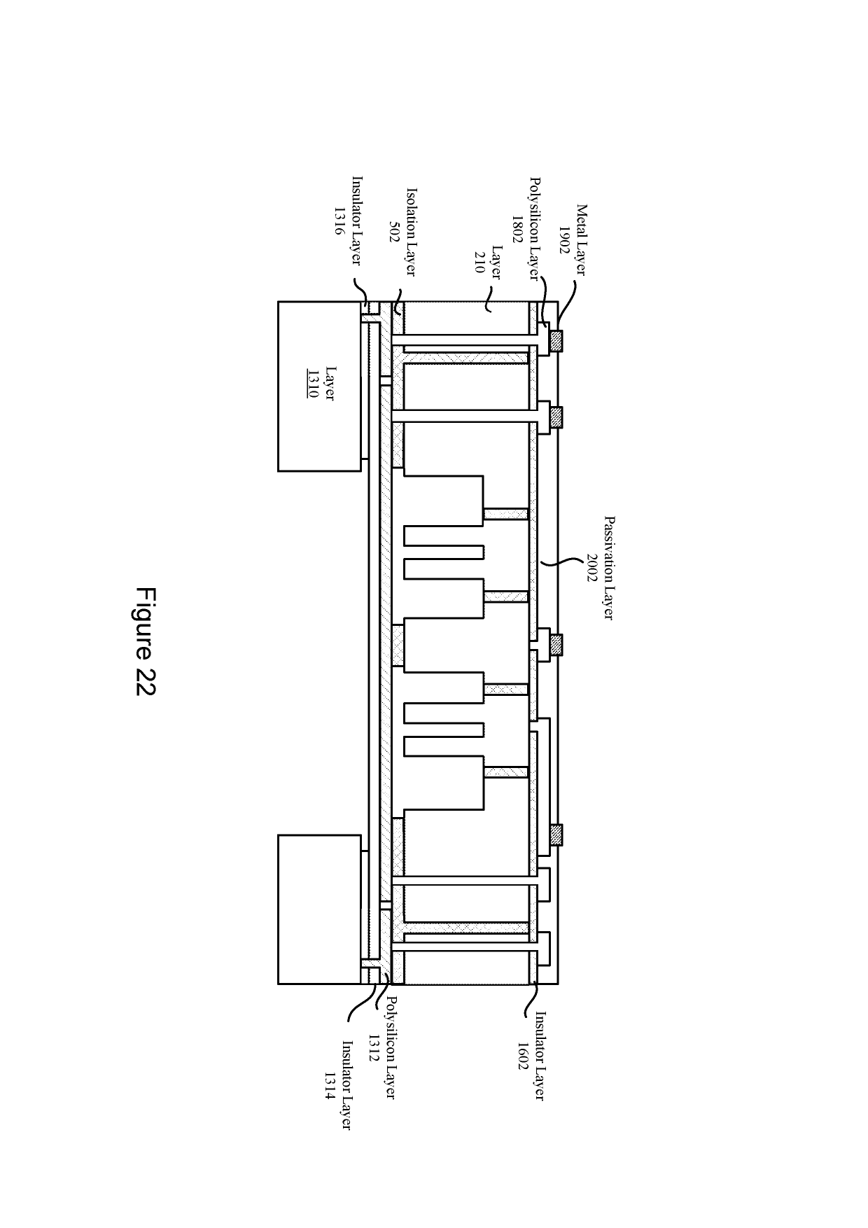

Referring now to FIG. 15, the layer 210 is thinned. For example, the first side of the layer 210 may be thinned to expose the isolation material 302 of the isolation trenches. The thinning process may include a wet SiO2 etch and Si CMP process. In one nonlimiting example, the thickness of the layer 210 may be greater than 20 µm. Referring now to FIG. 16, an insulator layer 1602, e.g., SiO2, may be deposited (chemical vapor deposition (CVD) and N2 anneal or thermal oxidation). It is appreciated that insulator layer 1602 deposition using thermal oxidation may cause oxygen and hydrogen to penetrate the cavities through SiO2 and oxidize the silicon inside the cavity. The insulator layer 1602 is patterned to protect the isolation material 302 filling the isolation trenches in order to pattern the first side of the layer 210 for contact (e.g., electrical contact). Referring now to FIG. 17, the exposed surfaces of the layer 210 (not covered by the insulator layer 1602) may be etched to create vias and to expose the polysilicon layer 1312. Referring now to FIG. 18, a polysilicon layer 1802 is deposited within the vias created (in FIG. 17) within the layer 210 to reach the polysilicon layer 1312. The polysilicon layer 1802 deposition may occur in low pressure chemical vapor deposition (LPCVD) and subsequently go through an anneal process for activation, stress control, and silicon to silicon contact. The polysilicon layer 1802 is patterned and a metal layer 1902 is deposited on the exposed polysilicon layer 1802, as shown in FIG. 19. Referring now to FIG. 20, a passivation layer 2002, e.g., SiN, is deposited over the exposed surfaces of the insulator layer 1602 and exposed surfaces of polysilicon layer 1802 while leaving the metal layer 1902 exposed for providing electrical connections. It is appreciated that the passivation layer 2002 may reduce gas leak path in the vertical direction.

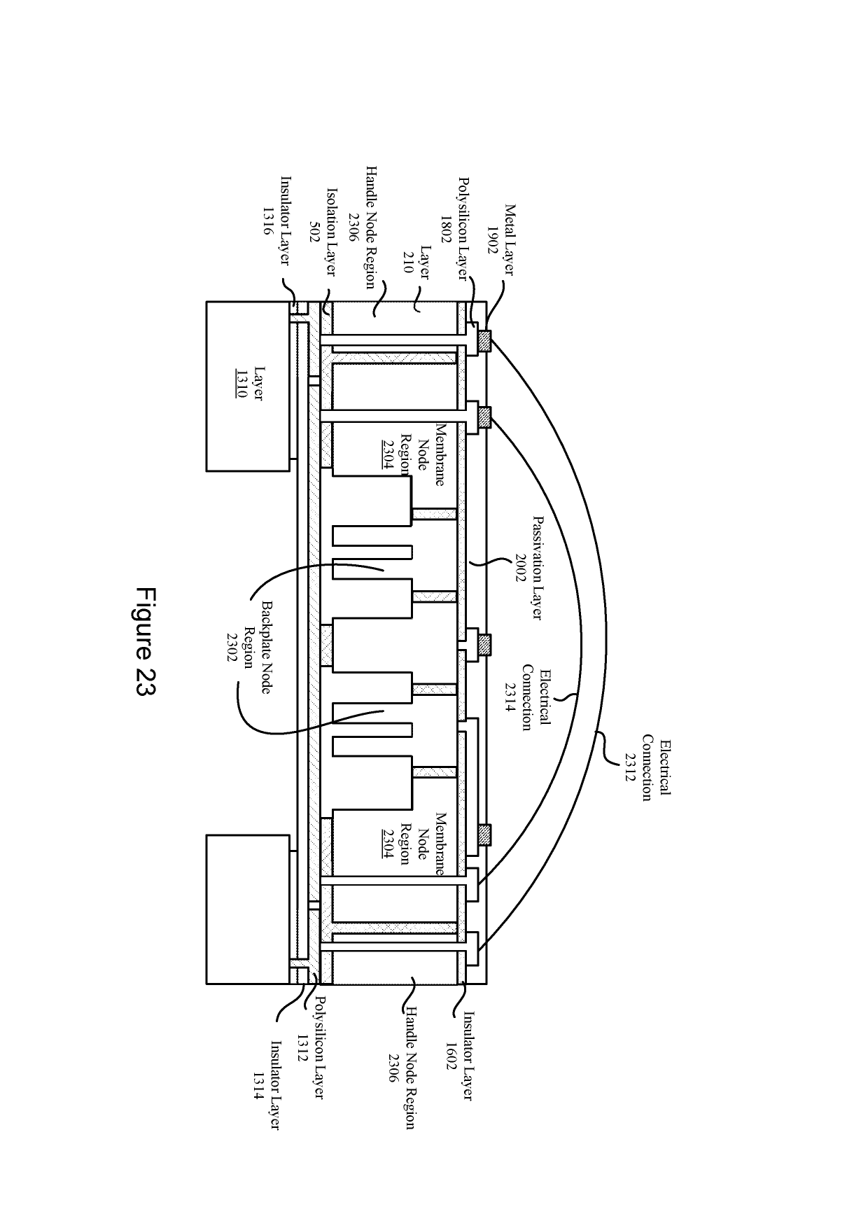

Referring now to FIG. 21, the first side of the layer 1310 is patterned cover a portion of the first side of the layer 1310 that align with the cavities formed within the layer 210 while leaving a portion of the first side of the layer 1310 that aligns with the cavities formed within the layer 210 exposed. As such, the exposed portions of the layer 1310 may be etched, e.g., DRIE, from the first side to expose the insulator layer 1316 where the etched portion forms acoustic port 2102. Referring now to FIG. 22, an exposed portion of the insulator 1316 may be removed to expose the insulator layer 1314. The insulator layer 1314 that is exposed as well as the polysilicon layer 1312 that is in contact with the insulator layer 1314 forms the deformable membrane of the microphone and it may also reduce gas leak path in the vertical direction. As such, acoustic wave as a stimuli causes the deformable membrane within the acoustic port 2102 to bend (or vibrates), thereby changing the distance between the sensing electrode polysilicon 1312 with respect to the sensing electrodes formed on the surfaces of the protruding portions and to change capacitance value, thereby detecting audio. It is appreciated that the polysilicon layer 1802 and/or the polysilicon layer 1312 may reduce gas leak path laterally. It is appreciated that the process may further include a self-assembled monolayer (SAM) coating process.

Referring now to FIG. 23, forming electrical connection between the electrical contacts according to one aspect of the present embodiments is shown. In one nonlimiting example, the backplate node region 2302, membrane node region 2304, and handle node region 2306 are formed and are electrically isolated from one another by the isolation material 302 filling the isolation trenches. The electrical connection 2312, e.g., a wire connection, may electrically connect the handle node region 2306 together while electrical connection 2314 may electrically connect the membrane node region 2304 together.

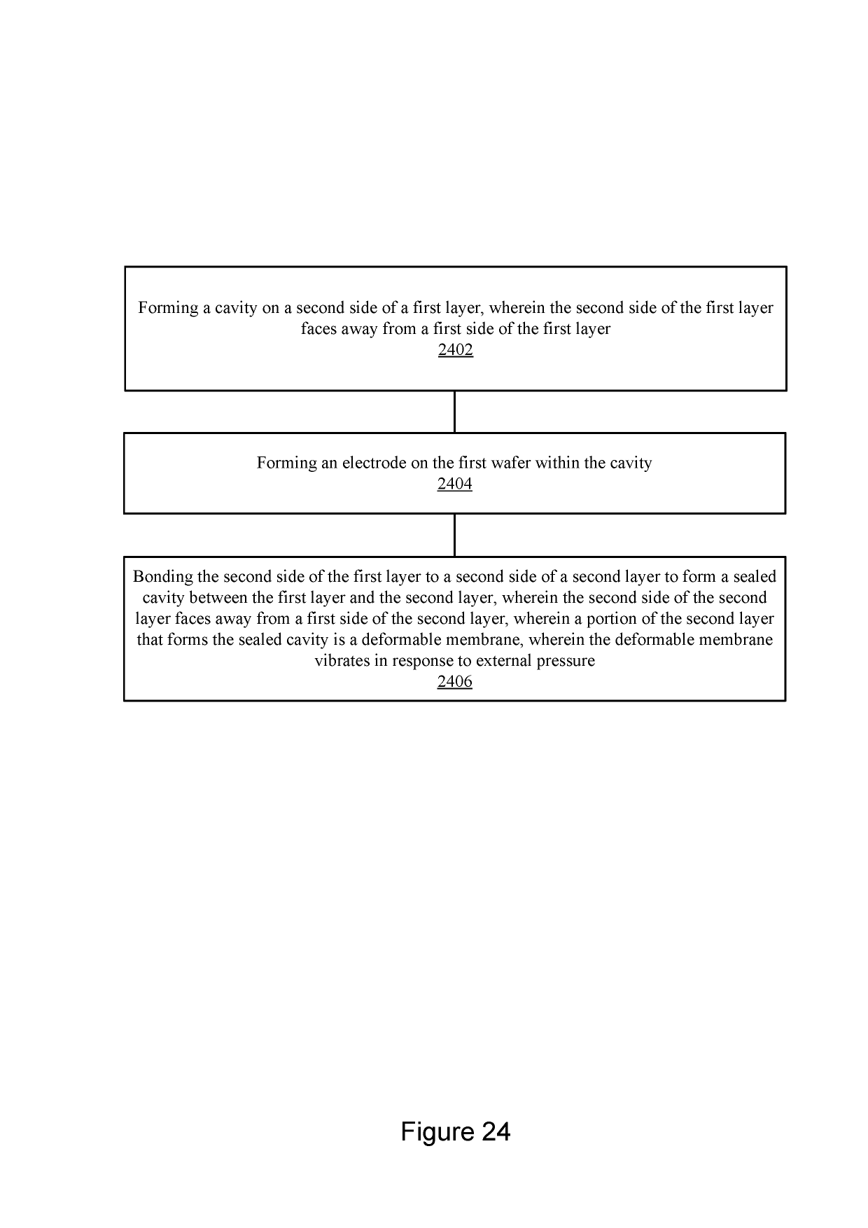

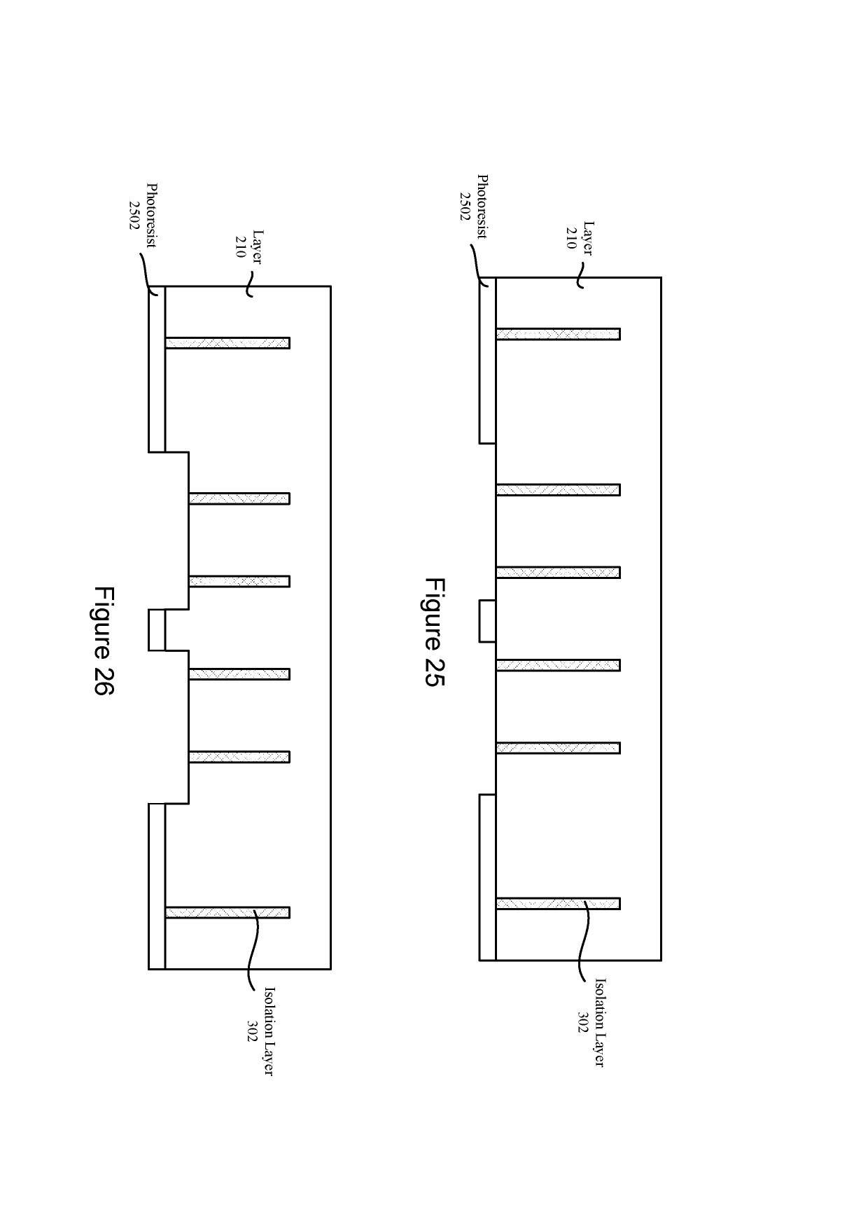

FIG. 24 shows a flow diagram for forming the microphone device according to one aspect of the present embodiments. At step 2402, a cavity on a second side of a first layer is formed, as described in FIGS. 1-23. The second side of the first layer faces away from a first side of the first layer. At step 2404, an electrode is formed on the first layer within the cavity, as described above. At step 2406, the second side of the first layer is bonded to a second side of a second layer to form a sealed cavity between the first layer and the second layer, as described in FIGS. 1-23. The second side of the second layer faces away from a first side of the second layer. According to one nonlimiting example, a portion of the second layer that forms the sealed cavity is a deformable membrane that vibrates in response to external pressure, e.g., acoustic wave.

According to one nonlimiting example, the method includes etching a portion of the second layer from the first side to form an acoustic port, e.g., etching a silicon dioxide layer on the second layer to expose the deformable membrane, as described in FIGS. 1-23. A plurality of electrically isolation regions may be formed within the first layer, as described above. In one nonlimiting example, the plurality of electrically isolated regions within the first layer is formed by forming a plurality of trenches within the second side of the first layer and by forming thermal oxidation within the plurality of trenches and on the second side of the first layer. The first layer from the first side of the first layer may be thinned to expose a surface of the plurality of electrically isolation regions. In one nonlimiting example, an insulator layer may be deposited on the exposed surface of the plurality of electrically isolated region and further on a portion of the first side of the first layer that is exposed. In one nonlimiting example, at least one or more electrical contacts are formed on the first side of the first layer, wherein the one or more electrical contacts is formed on another portion of the first side of the first layer that is exposed. According to some embodiments, a passivation layer is formed on the first side of the first layer and between the at least one or more electrical contacts. In some nonlimiting examples, a first standoff is formed outside the cavity of the second side of the first layer and a second standoff (e.g., silicon dioxide) is formed on the second side of the first layer. The first standoff and the second standoff are bonded (e.g., fusion bond between silicon dioxide) to the polysilicon layer of the second layer. In one nonlimiting example, the cavity in the first layer is etched to form a plurality of cavities and protruding portions, wherein the protruding portions form backplate electrodes.

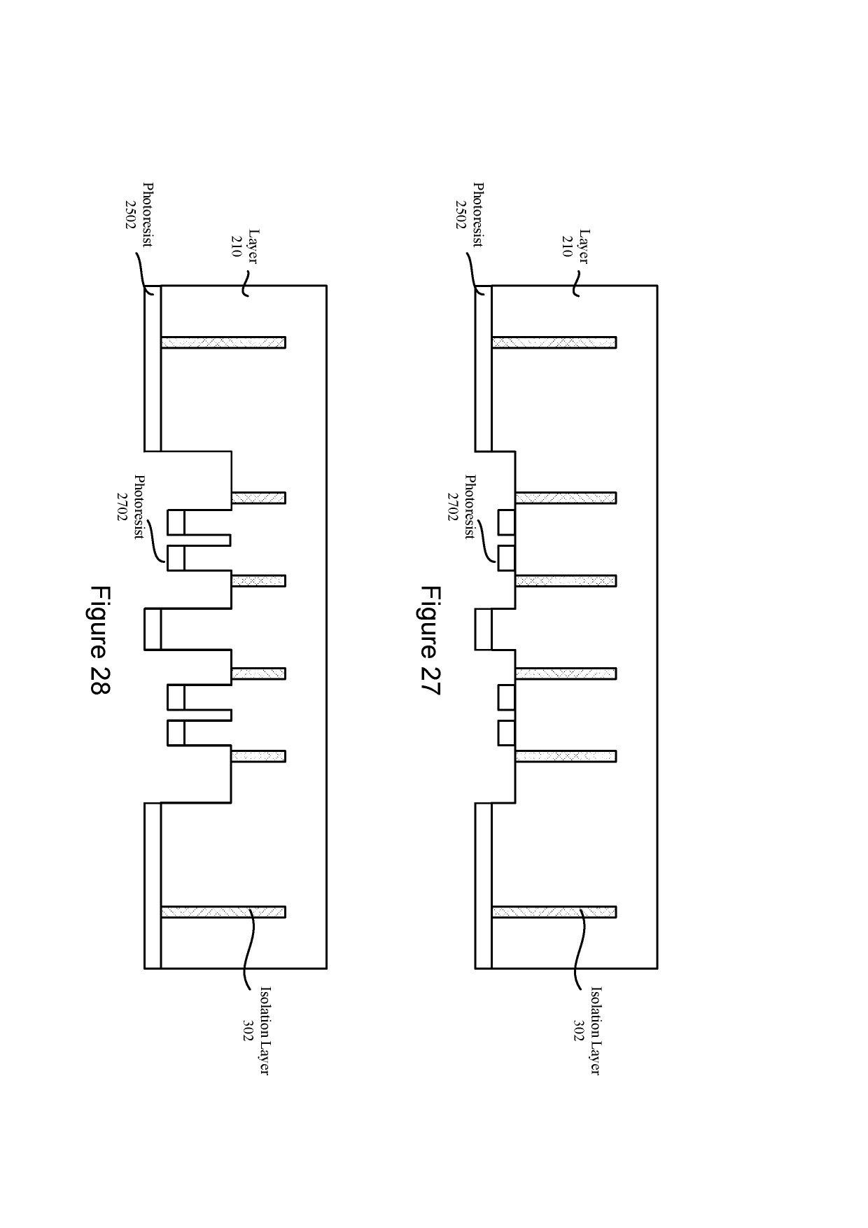

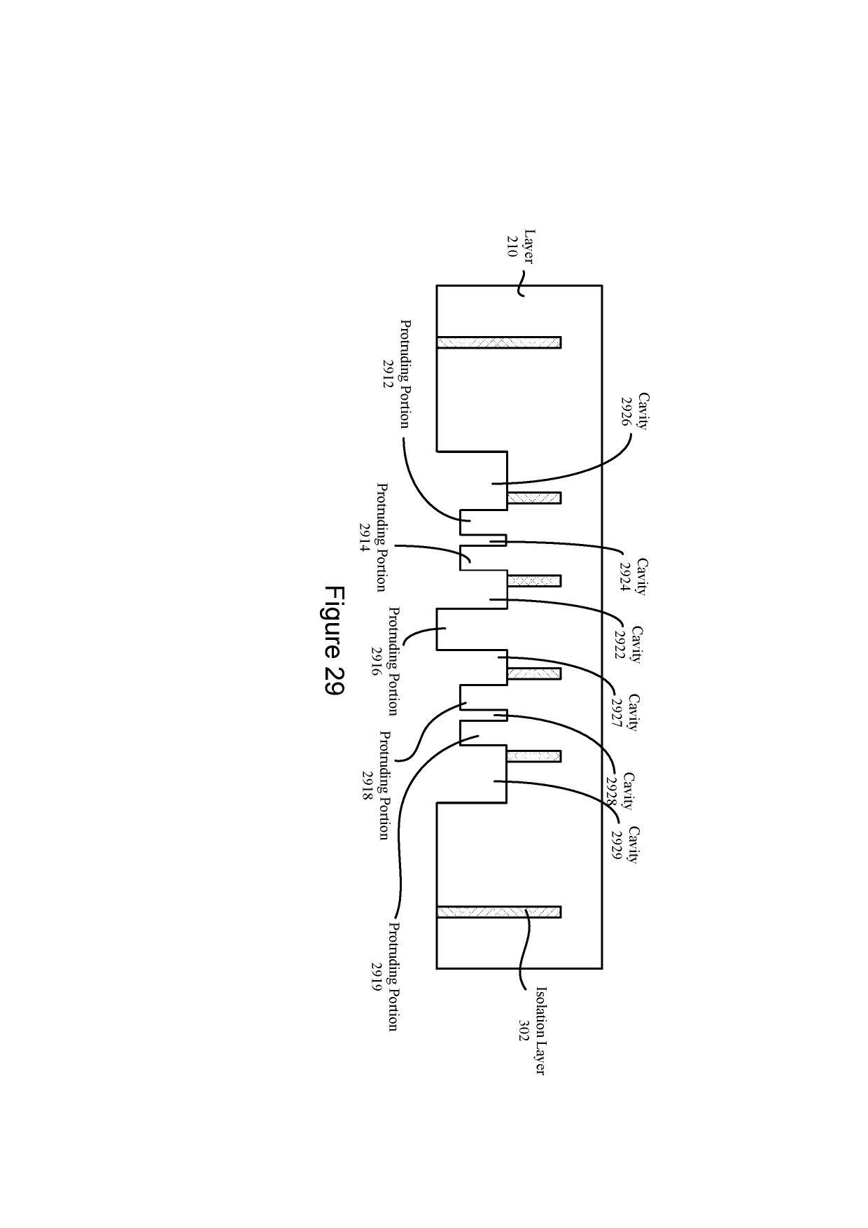

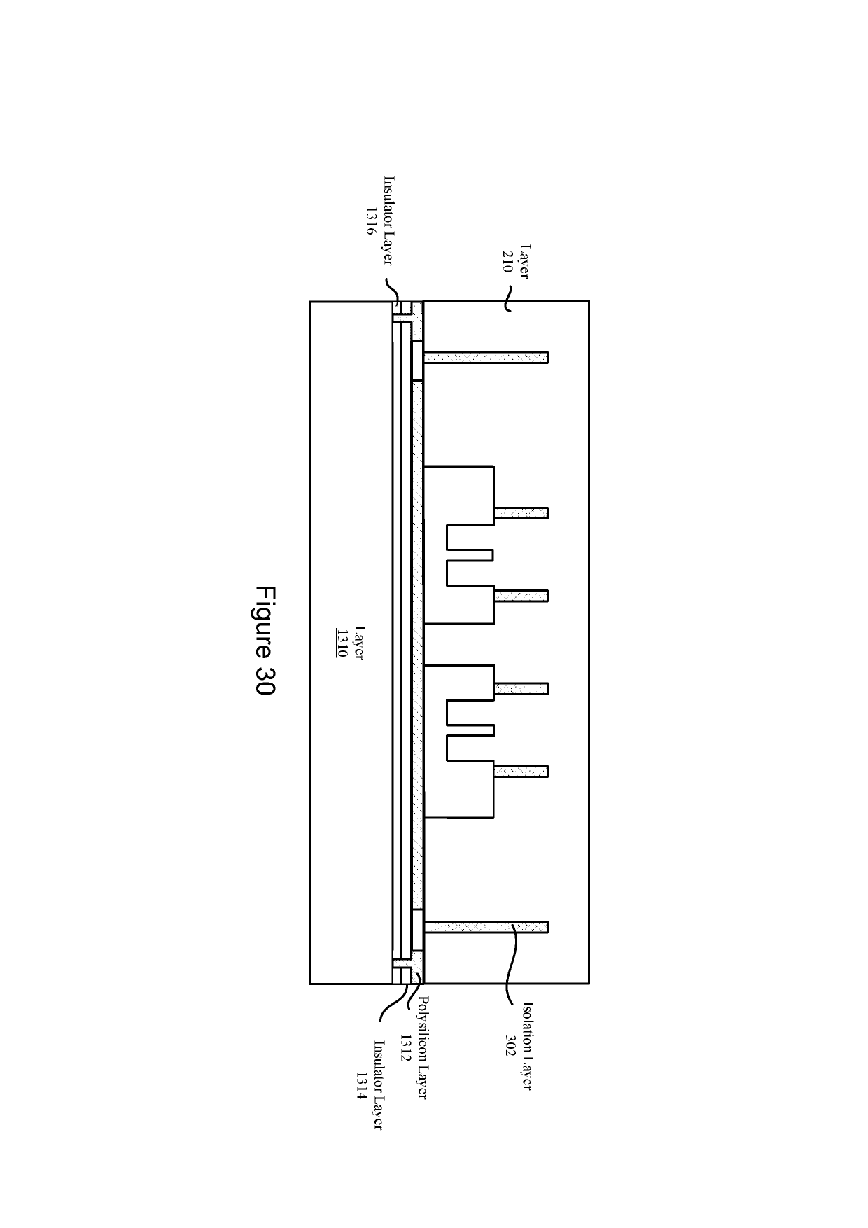

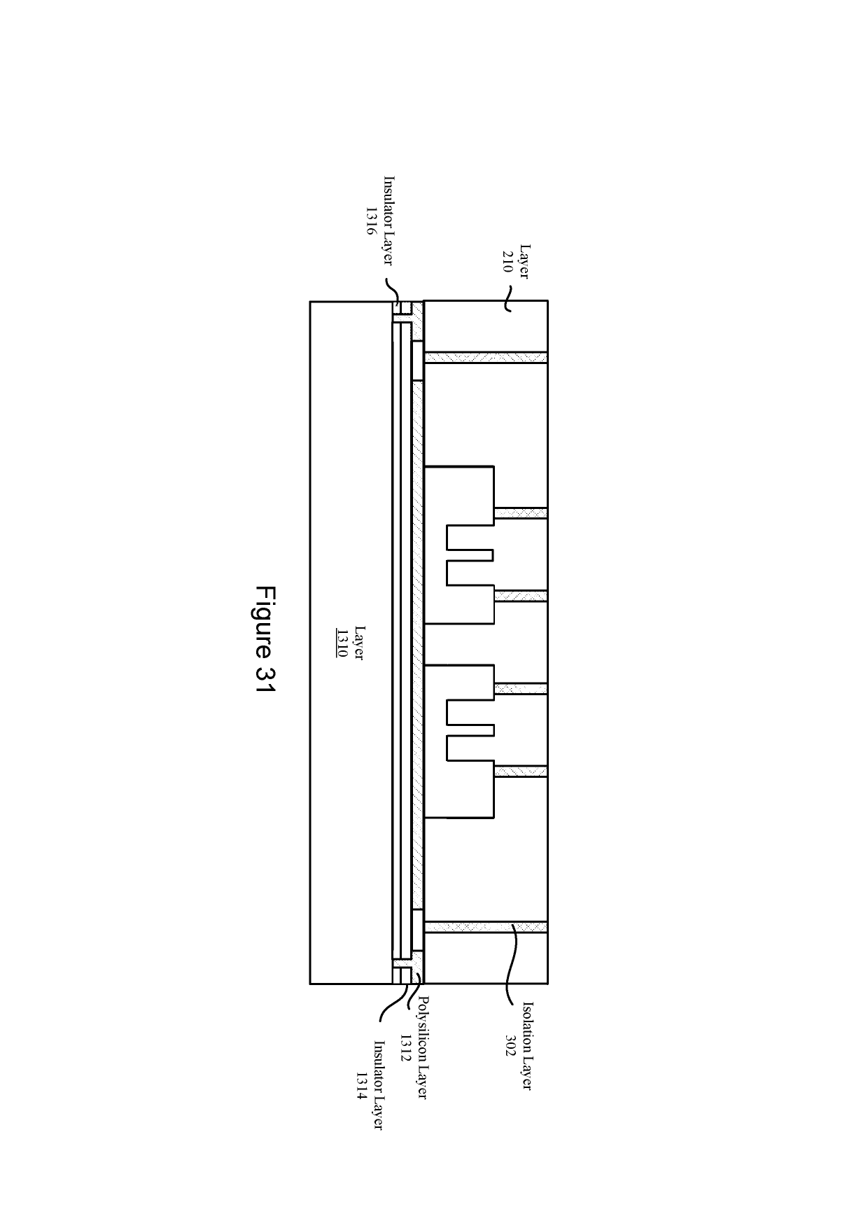

Referring now to FIGS. 25-29, another nonlimiting example of forming a backplate of the microphone device according to one aspect of the present embodiments is shown. A photoresist 2502 is formed over the second side of the layer 210 of FIG. 4, and is patterned, as shown in FIG. 25. Accordingly, certain surface of the layer 210 on the second side is covered by the photoresist 2502 while other portions are on the second side is exposed. Referring now to FIG. 26, the exposed portions on the second side of the layer 210 is etched to form cavities on the second side of the layer 210. Referring now to FIG. 27, a photoresist layer 2702 is formed within the cavities and patterned where the photoresist layer 2702 protects the second side of the layer 210 from etching in order to form the protruding portions. Referring now to FIG. 28, the exposed portions of the layer 210 (not covered by the photoresist layers 2502 and 2702) on the second side are etched. As such, cavities that are deeper are formed and further the protruding portions are formed. Referring now to FIG. 29, the photoresist layers 2502 and 2702 are removed. Accordingly, the cavities 2922, 2924, and 2926-2929, and protruding portions 2912-2919 are formed. The sensing electrodes of the backplate may be formed on the surfaces of the protruding portions 2912-2914 and/or 2918-2919.

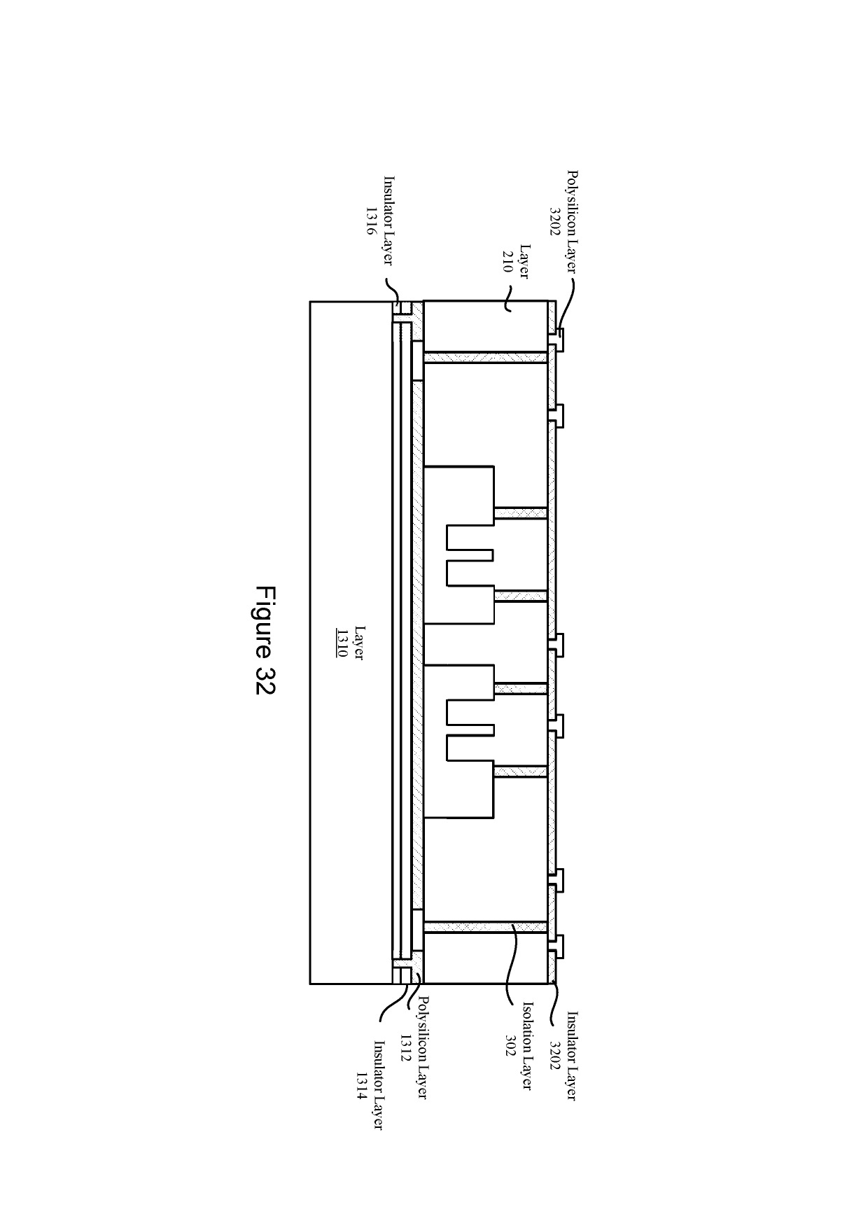

Referring now to FIG. 30, bonding the backplate (as shown in FIG. 29) of the microphone device to a membrane layer (as shown in FIGS. 13) according to one aspect of the present embodiments. The bonding may be through fusion bonding of the two layers, as described above.

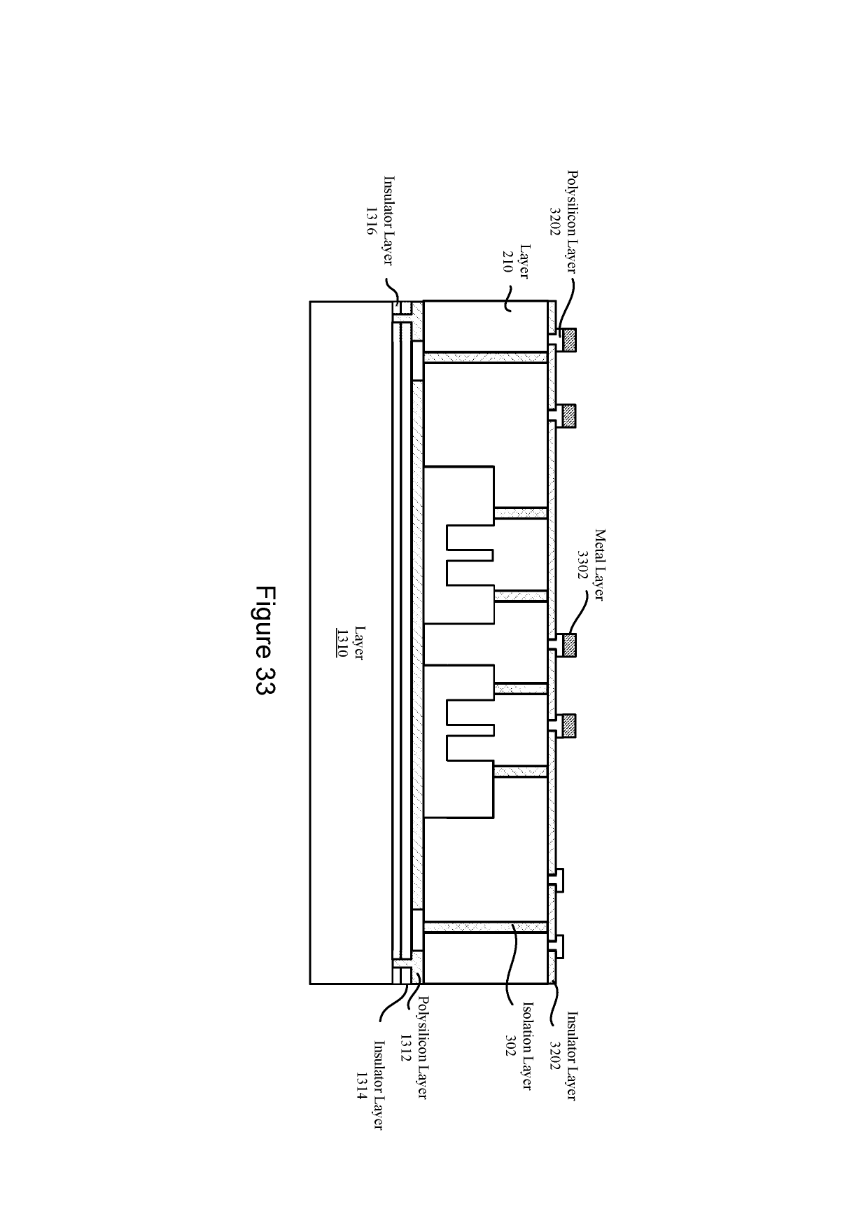

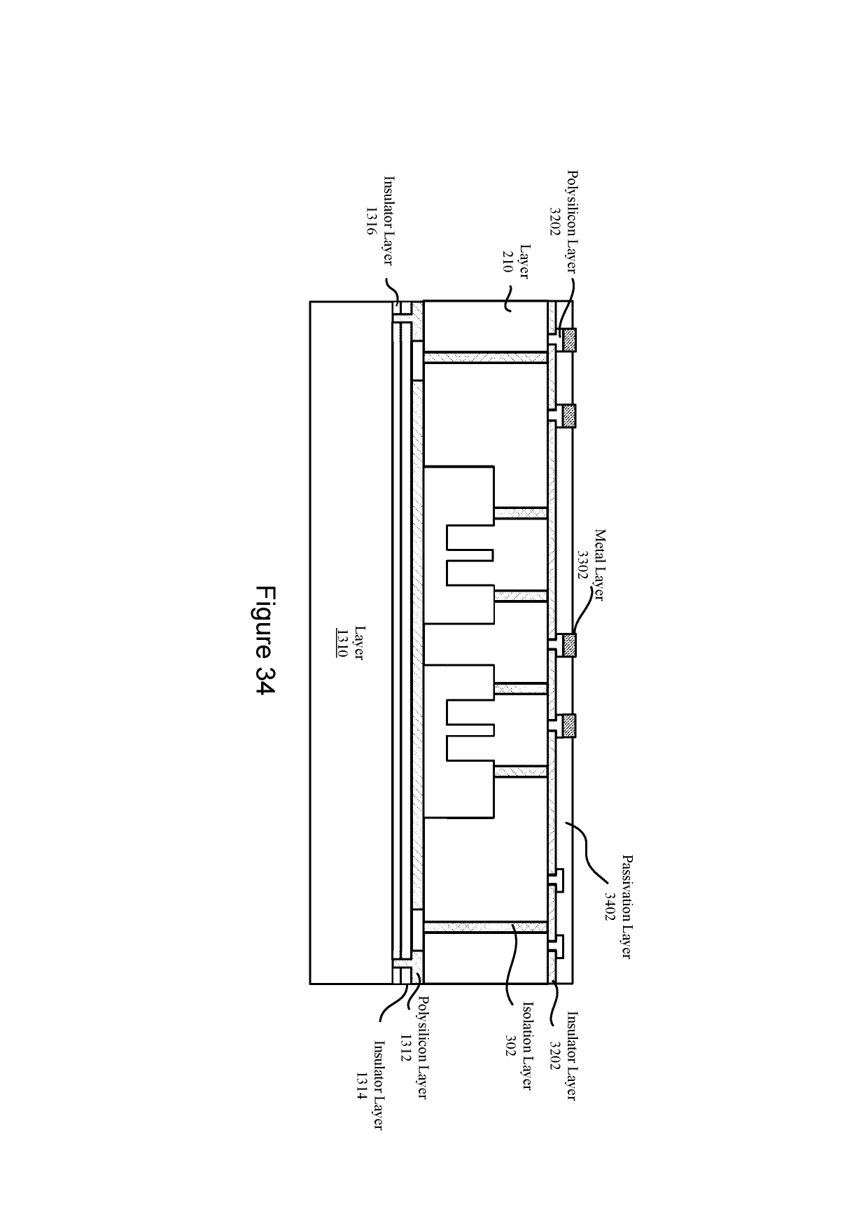

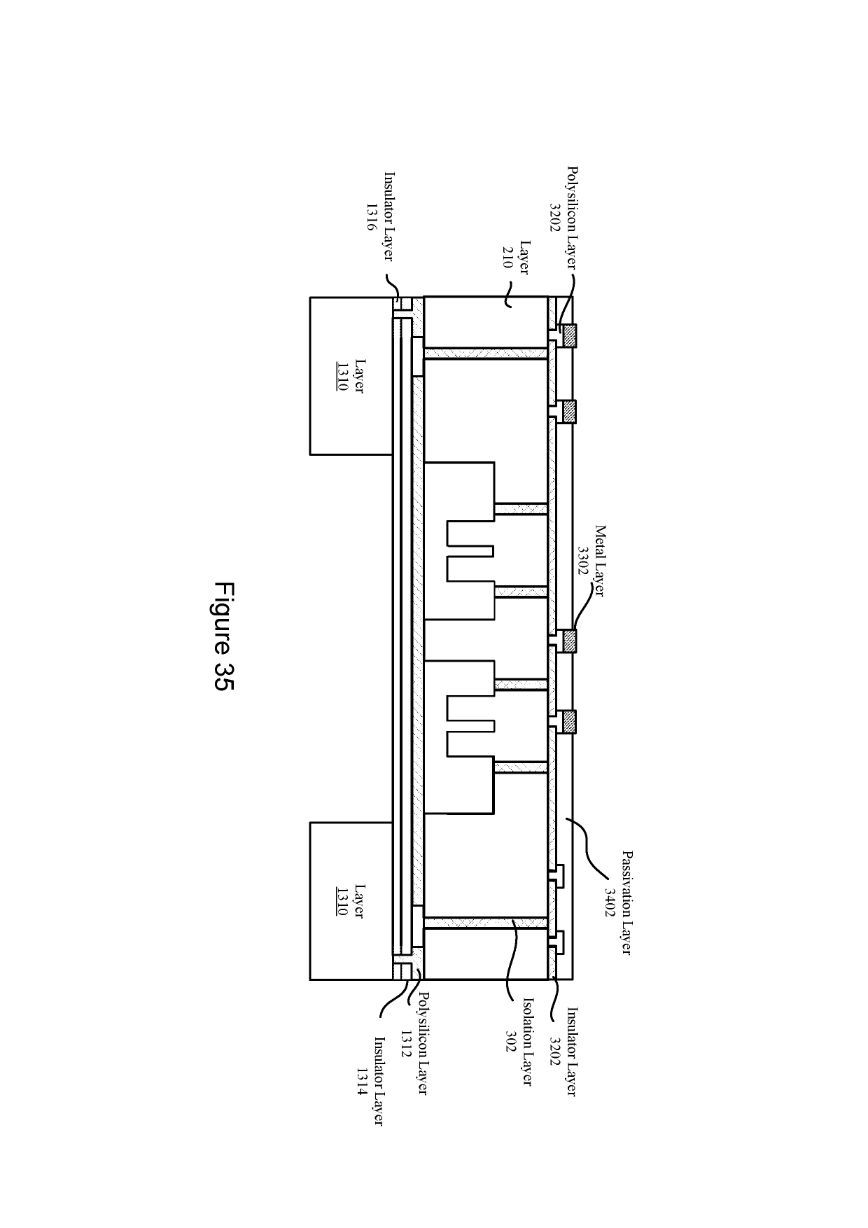

Referring now to FIGS. 31-34, formation of electrical connections on the backplate of the microphone device according to one aspect of the present embodiments is shown. In FIG. 31, the layer 210 is thinned from the first side, as described above, to expose the isolation layer 302 of the isolation trenches within the layer 210. Referring now to FIG. 32, an insulator layer 3202 is deposited on the first side of the layer 210, as described above, and is patterned. A polysilicon layer 3202 may be formed on the exposed surfaces of the layer 210 from the first side as well as covering a portion of the insulator layer 3202. Referring now to FIG. 33, a metal layer 3302 is formed over at least one portion of the polysilicon layer 3202 for making electrical connections. A passivation layer 3402, e.g., SiN, may be deposited over the insulator layer 3202 while leaving the top surface of the metal layer 3302 exposed.

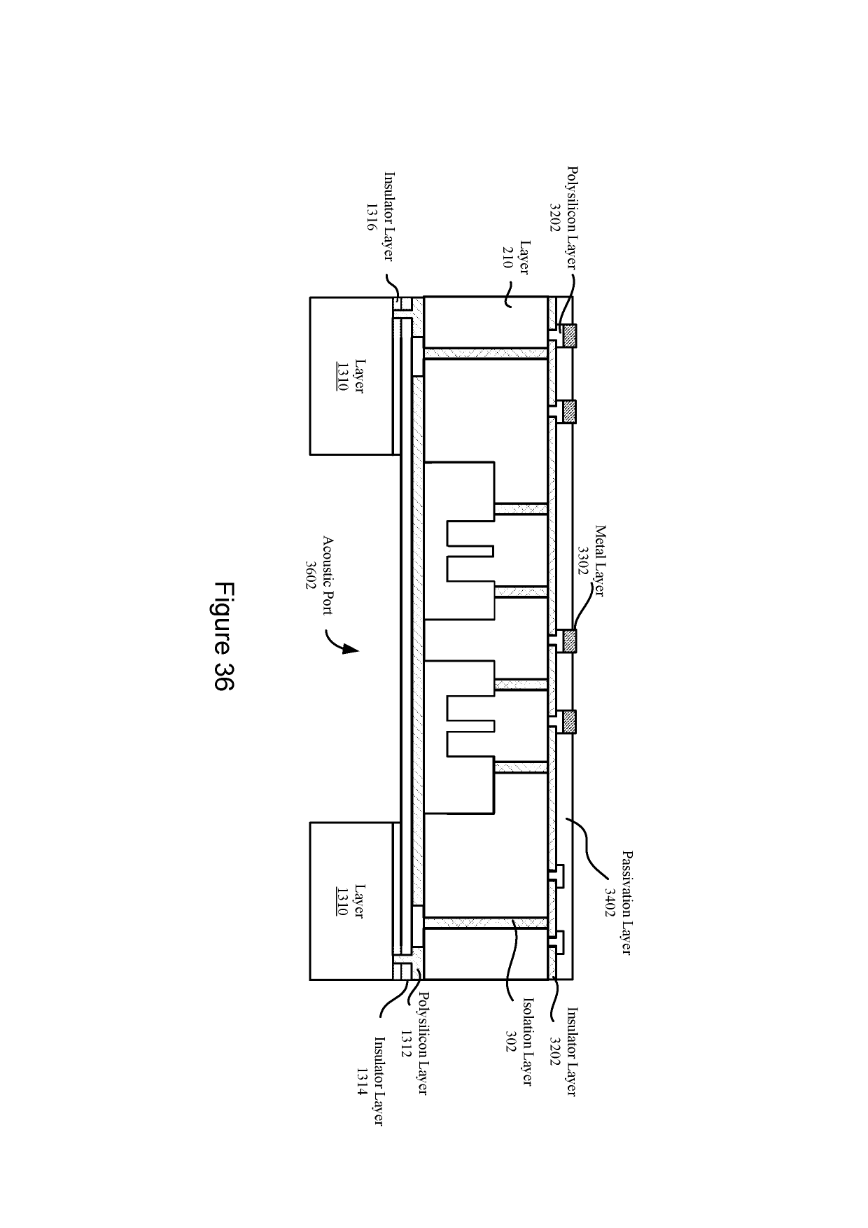

Referring now to FIGS. 35-36, forming an acoustic port of the microphone device according to one aspect of the present embodiments are shown. Similar to FIGS. 21-22, a portion of the layer 1310 is etched to expose a surface of the insulator layer 1316, which is subsequently etched to expose the insulator layer 1314. As illustrated, the polysilicon layer 1312 and the exposed portion of the insulator layer 1314 formed the movable membrane of the deformable membrane. The polysilicon layer 1312 is an electrode of the deformable membrane that moves (vibrates) in response to pressure, e.g., acoustic wave. The distance between the polysilicon layer 1312 and the sensing electrode formed on the protruding portions 2912, 2914, 2918, and 2919 that are stationary changes in response to pressure, thereby changing capacitance value. As such, acoustic wave is sensed. As illustrated, the manufacturing process, as described in FIGS. 25-36, differs from that of FIGS. 5-23 in that in FIGS. 5-23 electrical connections are formed as vias while in FIGS. 25-36 no vias are formed. Moreover, the gap between the sensing electrodes is controlled using thermal oxidation in FIGS. 5-23 while in FIGS. 25-36 the bulk silicon is used and etched to control the gap.

As illustrated, two layers, e.g., two wafers, may be processed concurrently in order to reduce the amount of time needed for manufacturing the microphone. Additionally, as discussed above, the gap between the surface of the protruding portion and the polysilicon layer underneath is controlled precisely. Additionally, the process as described above results in a thicker backplate, thereby reducing unwanted resonances and improving performance.

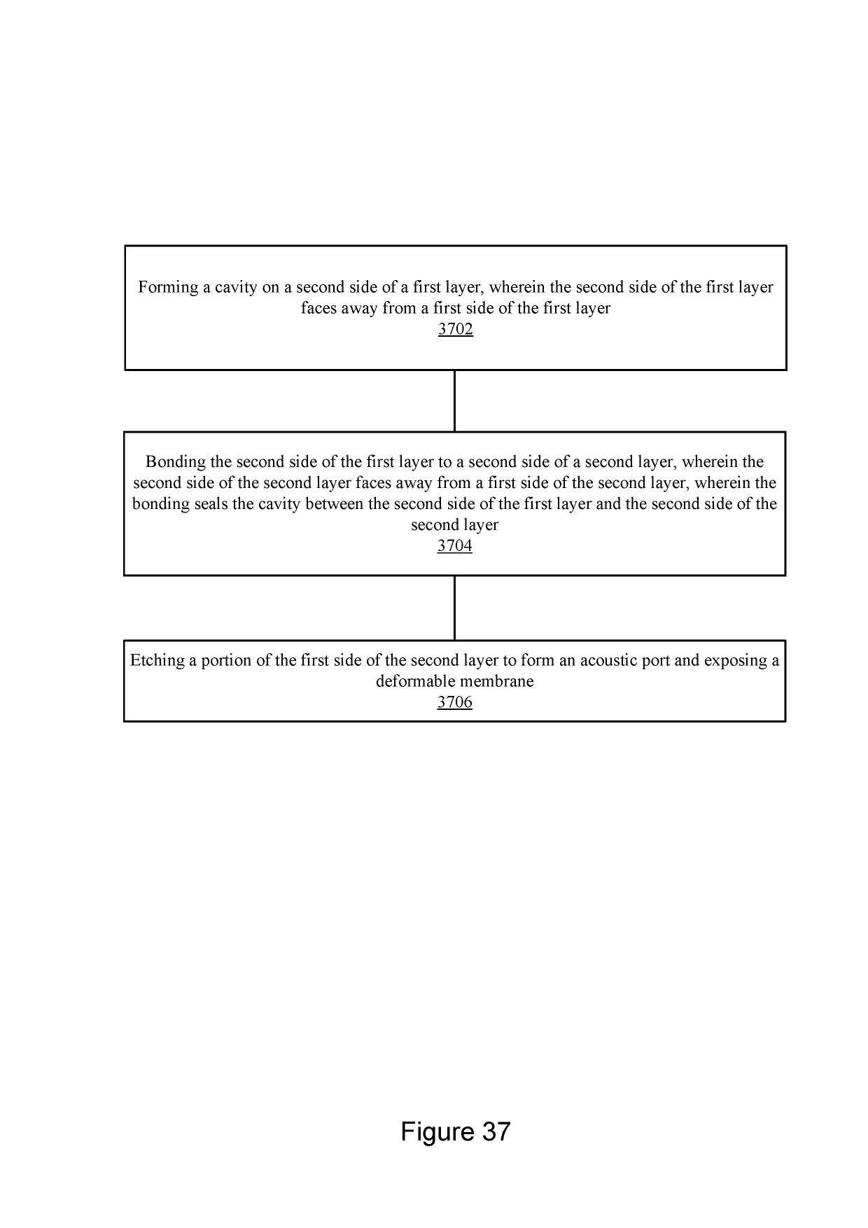

FIG. 37 shows a flow diagram for forming the microphone device according to another aspect of the present embodiments. At step 3702, a cavity is formed on a second side of a first layer, wherein the second side of the first layer faces away from a first side of the first layer, as described in FIGS. 25-36. At step 3704, the second side of the first layer is bonded to a second side of a second layer, as described in FIGS. 25-36. It is appreciated that the second side of the second layer faces away from a first side of the second layer, as described above. According to one nonlimiting example, the bonding seals the cavity between the second side of the first layer and the second side of the second layer, as described in FIGS. 25-36. At step 3706, a portion of the first side of the second layer is etched forming an acoustic port and exposing a deformable membrane, as described in FIGS. 25-36.

In one nonlimiting example, a plurality of electrically isolation regions is formed within the first layer, e.g., the plurality of electrically isolated regions within the first layer is formed by forming a plurality of trenches within the second side of the first layer and by forming thermal oxidation within the plurality of trenches and on the second side of the first layer, as described in FIGS. 25-36. According to one nonlimiting example, the first layer from the first side of the first layer is thinned to expose a surface of the plurality of electrically isolation regions, as described above. According to some embodiments, an insulator, e.g., silicon dioxide, silicon nitride, etc., is deposited on the exposed surface of the plurality of electrically isolated region and further on a portion of the first side of the first layer that is exposed, as described in FIGS. 25-36. In one nonlimiting example, the etching forms a plurality of cavities and protruding portions, wherein the protruding portions form backplate electrodes, as described in FIGS. 25-36. In one nonlimiting example, a first standoff is formed outside the cavity on the second side of the first layer, as described above. In some embodiments, a center standoff is formed on the second side of the first layer, as described in FIGS. 25-36. In one nonlimiting example, a height of the center standoff is controlled through a thermal oxidation, as described above. According to one nonlimiting example, the first standoff and the center standoff are formed from an insulator layer, e.g., silicon dioxide or silicon nitride. According to one nonlimiting example, the bonding comprises forming fusion bonding the first standoff and the center standoff to the second layer.

While the embodiments have been described and/or illustrated by means of particular examples, and while these embodiments and/or examples have been described in considerable detail, it is not the intention of the Applicants to restrict or in any way limit the scope of the embodiments to such detail. Additional adaptations and/or modifications of the embodiments may readily appear, and, in its broader aspects, the embodiments may encompass these adaptations and/or modifications. Accordingly, departures may be made from the foregoing embodiments and/or examples without departing from the scope of the concepts described herein. The implementations described above and other implementations are within the scope of the following claims.

What is claimed is:

1. A method comprising:
forming a cavity on a second side of a first layer, wherein the second side of the first layer faces away from a first side of the first layer;
etching the cavity to form a plurality of cavities and protruding portions, wherein the protruding portions form backplate electrodes;
bonding the second side of the first layer to a second side of a second layer,
wherein the second side of the second layer faces away from a first side of the second layer,
wherein the bonding seals the cavity between the second side of the first layer and the second side of the second layer; and
after the bonding, etching a portion of the first side of the second layer, forming an acoustic port and exposing a deformable membrane.

2. The method of claim 1 further comprising forming a plurality of electrically isolation regions within the first layer.

3. The method of claim 2 further comprising thinning the first layer from the first side of the first layer to expose a surface of the plurality of electrically isolation regions.

4. The method of claim 3 further comprising depositing an insulator on the exposed surface of the plurality of electrically isolated region and further on a portion of the first side of the first layer that is exposed.

5. The method of claim 3, wherein the insulator is any of silicon dioxide or silicon nitride.

6. The method of claim 4 further comprising forming at least one or more electrical contacts on the first side of the first layer, wherein the one or more electrical contacts is formed on another portion of the first side of the first layer that is exposed.

7. The method of claim 5 further comprising forming a passivation layer on the first side of the first layer and between the at least one or more electrical contacts.

8. The method of claim 2, wherein the plurality of electrically isolated regions within the first layer is formed by forming a plurality of trenches within the second side of the first layer and by forming thermal oxidation within the plurality of trenches and on the second side of the first layer.

9. The method of claim 1 further comprising forming a first standoff outside the cavity on the second side of the first layer.

10. The method of claim 9 further comprising forming a center standoff on the second side of the first layer.

11. The method of claim 9, where the first standoff and the center standoff are formed from an insulator layer.

12. The method of claim 11, wherein the insulator is any of silicon dioxide or silicon nitride, and wherein the bonding comprises forming fusion bonding the first standoff and the center standoff to the second layer.

13. The method of claim 11 further comprising controlling a height of the center standoff through a thermal oxidation.

14. A method comprising:
forming a cavity on a second side of a first layer, wherein the second side of the first layer faces away from a first side of the first layer;
forming an electrode on the first layer within the cavity; and
bonding the second side of the first layer to a second side of a second layer to form a sealed cavity between the first layer and the second layer, wherein the second side of the second layer faces away from a first side of the second layer, wherein a portion of the second layer that forms the sealed cavity is a deformable membrane, wherein the deformable membrane vibrates in response to external pressure.

15. The method of claim 14 further comprising etching a portion of the second layer from the first side to form an acoustic port.

16. The method of claim 15 further comprising etching a silicon dioxide layer on the second layer to expose the deformable membrane.

17. The method of claim 14 further comprising forming a plurality of electrically isolation regions within the first layer.

18. The method of claim 17 further comprising thinning the first layer from the first side of the first layer to expose a surface of the plurality of electrically isolation regions.

19. The method of claim 18 further comprising depositing an insulator layer on the exposed surface of the plurality of electrically isolated region and further on a portion of the first side of the first layer that is exposed.

20. The method of claim 19 further comprising forming at least one or more electrical contacts on the first side of the first layer, wherein the one or more electrical contacts is formed on another portion of the first side of the first layer that is exposed.

21. The method of claim 20 further comprising forming a passivation layer on the first side of the first layer and between the at least one or more electrical contacts.

22. The method of claim 17, wherein the plurality of electrically isolated regions within the first layer is formed by forming a plurality of trenches within the second side of the first layer and by forming thermal oxidation within the plurality of trenches and on the second side of the first layer.

23. The method of claim 14 further comprising forming a first standoff outside the cavity of the second side of the first layer and forming a second standoff on the second side of the first layer, wherein the first standoff and the second standoff are bonded to the polysilicon layer of the second layer.

24. The method of claim 23, wherein the second standoff is formed from silicon dioxide and the bond is a fusion bond between silicon dioxide and polysilicon on the second layer.

25. The method of claim 14 further comprising etching the cavity in the first layer to form a plurality of cavities and protruding portions, wherein the protruding portions form backplate electrodes.
